(19) United States
(12) Patent Application Publication
(10) Pub. No.: US 2026/0231489 A1
(43) Pub. Date: Aug. 6, 2026

(54) SEMICONDUCTOR DEVICE

(71) Applicant: FUJI ELECTRIC CO., LTD., Kanagawa (JP)

(72) Inventors: Tohru SHIRAKAWA, Matsumoto-city (JP); Kaname MITSUZUKA, Matsumoto-city (JP)

(21) Appl. No.: 19/575,798

(22) Filed: Mar. 23, 2026

Related U.S. Application Data
(63) Continuation of application No. PCT/JP2025/004007, filed on Feb. 6, 2025.

(30) Foreign Application Priority Data
Feb. 9, 2024 (JP) 2024-018541

(51) Int. Cl. H10D 62/13; H10D 12/00; H10D 84/00

(52) U.S. Cl. CPC H10D 62/145; H10D 12/481; H10D 84/161

(57) ABSTRACT

Provided is a semiconductor device comprising a drift region of a first conductivity type provided in a semiconductor substrate, a base region of a second conductivity type, an emitter region of a first conductivity type having a doping concentration higher than that of the drift region, a contact region of the second conductivity type, a trench contact portion, and trench portions extending in a predefined trench extending direction on a front-surface side of the semiconductor substrate, wherein the trench portions includes a gate trench portion and a dummy trench portion, and a mesa portion between the trench portions has a contact formation region where the contact region is provided below the emitter region on a sidewall of at least one trench portion, and a contact non-formation region where the contact region is not provided below the emitter region on a sidewall of the gate trench portion.

The contents of the following patent application(s) are incorporated herein by reference: NO. 2024-018541 filed in JP on February 9, 2024, and NO. PCT/JP2025/004007 filed in WO on February 6, 2025.

### BACKGROUND

### Technical Field

The present invention relates to a semiconductor device.

### Related Art

Conventionally, a semiconductor device including an N type emitter region and a P type contact region has been known (see, for example, Patent Documents 1 and 2).

Patent Literature 1: Japanese Patent Application Publication No. 2023-096841

Patent Literature 2: International Publication No. 2018/052098

### BRIEF DESCRIPTION OF THE DRAWINGS

FIG. 1 illustrates an example of a top view of a semiconductor device 100.

FIG. 2A is an enlarged view of a region A in FIG. 1.

FIG. 2B illustrates an example of an XZ cross section including an a-a’ cross section in FIG. 2A.

FIG. 2C illustrates an example of an XZ cross section including a b-b’ cross section in FIG. 2A.

FIG. 2D illustrates an example of a YZ cross section including a c-c' cross section in FIG. 2A.

FIG. 2E is an enlarged view illustrating an example of an XZ cross section in an area Q of a transistor portion 70 of the semiconductor device 100 in FIG. 2B.

FIG. 2F illustrates an example of a YZ cross section including a g-g' cross section in FIG. 2A.

FIG. 3A illustrates a top view of a modification example of the semiconductor device 100.

FIG. 3B illustrates an example of an XZ cross section including a d-d’ cross section in FIG. 3A.

FIG. 3C illustrates an example of an XZ cross section including an e-e' cross section in FIG. 3A.

FIG. 3D illustrates an example of a YZ cross section including a f-f' cross section in FIG. 3A.

FIG. 4A illustrates a enlarged top view of a modification example of the semiconductor device 100.

FIG. 4B represents an example of a XZ cross section of the semiconductor device 100 illustrated in FIG. 4A.

FIG. 4C is an enlarged view illustrating an example of a XZ cross section of the semiconductor device 100.

FIG. 4D is an enlarged view illustrating a modification example of a XZ cross section of the semiconductor device 100.

FIG. 5A illustrates a enlarged top view of a modification example of the semiconductor device 100.

FIG. 5B illustrates an example of an XZ cross section of the semiconductor device 100 illustrated in FIG. 5A.

FIG. 6 is an enlarged view illustrating an example of a XZ cross section of the semiconductor device 100.

FIG. 7A illustrates a enlarged top view of a modification example of the semiconductor device 100.

FIG. 7B is an enlarged view illustrating an example of an XZ cross section of the semiconductor device 100.

FIG. 8 illustrates an example of an x-x' cross section in FIG. 1.

FIG. 9 illustrates an example of a manufacturing method of the semiconductor device 100.

FIG. 10A illustrates a top view of a semiconductor device 500 of a comparative example.

FIG. 10B represents a diagram illustrating an example of a YZ cross section including an i-i' cross section in FIG. 10A.

FIG. 11A describes a design method the semiconductor device 500 of the comparative example.

FIG. 11B describes an example of a design method of the semiconductor device 100.

### DESCRIPTION OF EXEMPLARY EMBODIMENTS

Hereinafter, the invention will be described through embodiments of the invention, but the following embodiments do not limit the invention according to claims. In addition, not all of the combinations of features described in the embodiments are essential to the solving means of the invention.

As used herein, one side in a direction parallel to a depth direction of a semiconductor substrate is referred to as “upper” and the other side is referred to as “lower”. One surface of two principal surfaces of a substrate, a layer or other member is referred to as an upper surface, and another surface is referred to as a lower surface. “Upper” and “lower” directions are not limited to a direction of gravity, or a direction in which a semiconductor device is mounted.

In the present specification, technical matters may be described using orthogonal coordinate axes of an X axis, a Y axis, and a Z axis. The orthogonal coordinate axes merely specify relative positions of components, and do not limit a specific direction. For example, the Z axis is not limited to indicate the height direction with respect to the ground. Note that a +Z axis direction and a -Z axis direction are directions opposite to each other. When the Z axis direction is described without describing the signs, it means that the direction is parallel to the +Z axis and the -Z axis.

In the present specification, orthogonal axes parallel to the upper surface and the lower surface of the semiconductor substrate are referred to as the X axis and the Y axis. Further, an axis perpendicular to the upper surface and the lower surface of the semiconductor substrate is referred to as the Z axis. In the present specification, the direction of the Z axis may be referred to as the depth direction. Further, in the present specification, a direction parallel to the upper surface and the lower surface of the semiconductor substrate may be referred to as a horizontal direction, including an X axis direction and a Y axis direction.

In the present specification, a case where a term such as “same” or “equal” is mentioned may include a case where an error due to a variation in manufacturing or the like is included. The error is, for example, within 10%.

In the present specification, a conductivity type of doping region where doping has been carried out with an impurity is described as a P type or an N type. In the present specification, the impurity may particularly mean either a donor of the N type or an acceptor of the P type, and may be described as a dopant. In the present specification, doping means introducing the donor or the acceptor into the semiconductor substrate and turning it into a semiconductor presenting a conductivity type of the N type, or a semiconductor presenting conductivity type of the P type.

In the present specification, a doping concentration means a concentration of the donor or a concentration of the acceptor in a thermal equilibrium state. In the present specification, a net doping concentration means a net concentration obtained by adding the donor concentration set as a positive ion concentration to the acceptor concentration set as a negative ion concentration, taking into account of polarities of charges. As an example, when the donor concentration is N_{D} and the acceptor concentration is N_{A}, the net doping concentration at any position is given as N_{D}-N_{A}. In the present specification, the net doping concentration may be simply referred to as the doping concentration.

In the present specification, a description of a P+ type or an N+ type means a higher doping concentration than that of the P type or the N type, and a description of a P- type or an N- type means a lower doping concentration than that of the P type or the N type. Further, in the specification, a description of a P++ type or an N++ type means a higher doping concentration than that of the P+ type or the N+ type.

A chemical concentration in the present specification indicates an atomic density of an impurity measured regardless of an electrical activation state. The chemical concentration can be measured by, for example, secondary ion mass spectrometry (SIMS). The net doping concentration described above can be measured by capacitance-voltage profiling (CV profiling). Further, a carrier concentration measured by spreading resistance profiling (SRP method) may be set as the net doping concentration. A carrier means an electron charge carrier or a hole charge carrier. The carrier concentration measured by the CV profiling or the SRP method may be a value in a thermal equilibrium state. Further, in a region of the N type, the donor concentration is sufficiently higher than the acceptor concentration, and thus the carrier concentration of the region may be set as the donor concentration. Similarly, in a region of the P type, the carrier concentration of the region may be set as the acceptor concentration. In the present specification, the doping concentration of the N type region may be referred to as the donor concentration, and the doping concentration of the P type region may be referred to as the acceptor concentration.

Further, when a concentration distribution of the donor, acceptor, or net doping has a peak in a region, a value of the peak may be set as the concentration of the donor, acceptor, or net doping in the region. In a case where the concentration of the donor, acceptor or net doping is substantially uniform in a region, or the like, an average value of the concentration of the donor, acceptor or net doping in the region may be set as the concentration of the donor, acceptor or net doping.

The carrier concentration measured by the SRP method may be lower than the concentration of the donor or the acceptor. In a range where a current flows when a spreading resistance is measured, carrier mobility of the semiconductor substrate may be lower than a value in a crystalline state. The reduction in carrier mobility occurs when carriers are scattered due to disorder (disorder) of a crystal structure due to a lattice defect or the like. The carrier concentration becomes lower for the following reason. In the SRP method, a spreading resistance is measured, and a carrier concentration is converted from a measurement value of the spreading resistance. At this time, mobility of the crystalline state is used as the carrier mobility. Meanwhile, despite the fact that carrier mobility is reduced at a position where the lattice defect is introduced, the carrier concentration is calculated by using the carrier mobility of the crystalline state. Therefore, a value lower than an actual carrier concentration, i.e., a concentration of donors or acceptors, is obtained.

The concentration of the donor or the acceptor calculated from the carrier concentration measured by the CV profiling or the SRP method may be lower than a chemical concentration of an element indicating the donor or the acceptor. As an example, in a silicon semiconductor, a donor concentration of phosphorus or arsenic serving as a donor, or an acceptor concentration of boron (boron) serving as an acceptor is approximately 99% of chemical concentrations of these. On the other hand, in the silicon semiconductor, a donor concentration of hydrogen serving as a donor is approximately 0.1% to 10% of a chemical concentration of hydrogen. In the present specification, an SI unit system is adopted. In the present specification, a unit of a distance or length may be represented by cm (centimeter). In this case, various calculations may be converted into m (meter) to be calculated. As for numeric representation of power of 10, for example, the representation 1E+16 indicates 1 × 10¹⁶, and the representation 1E-16 indicates 1 × 10⁻¹⁶.

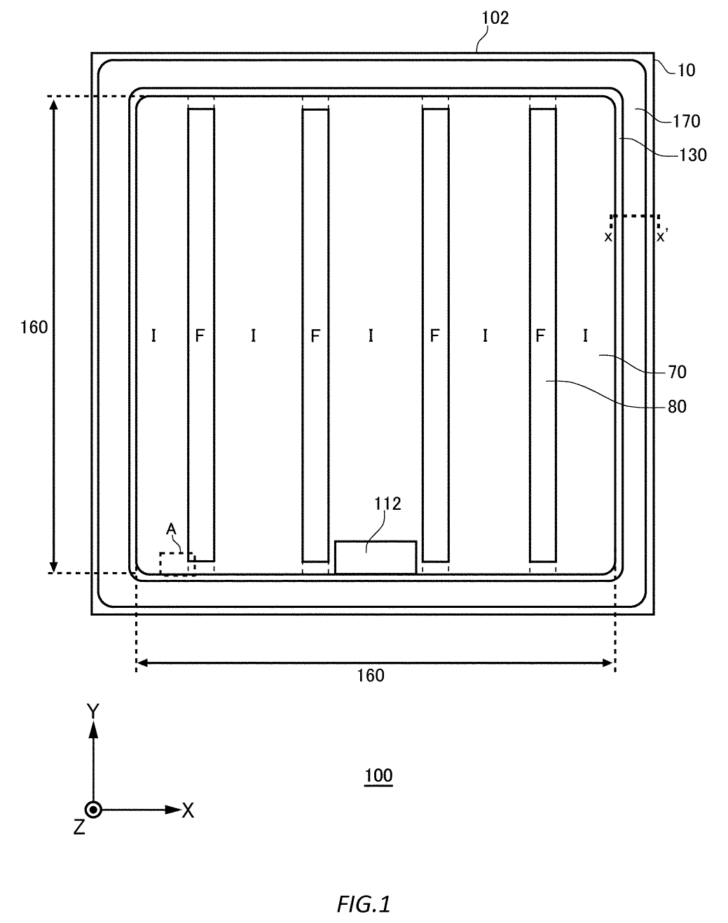

FIG. 1 illustrates an example of a top view of a semiconductor device 100. FIG. 1 shows a position at which each member is projected on an upper surface of a semiconductor substrate 10. FIG. 1 shows merely some members of the semiconductor device 100, and omits illustrations of some members. The semiconductor device 100 is a semiconductor chip including a transistor portion 70 and a diode portion 80.

The transistor portion 70 includes a transistor such as an IGBT (Insulated Gate Bipolar Transistor). The diode portion 80 includes a diode such as a freewheeling diode (FWD). The semiconductor device 100 of this example is a reverse conducting IGBT (RC-IGBT) having the transistor portion 70 and the diode portion 80 on the same chip.

The semiconductor substrate 10 is a substrate that is formed of a semiconductor material. The semiconductor substrate 10 may be a silicon substrate, may be a silicon carbide substrate, may be a diamond substrate, may be a nitride semiconductor substrate such as gallium nitride, may be an inorganic compound semiconductor substrate such as gallium oxide, or may be an organic compound semiconductor substrate. The semiconductor substrate 10 in this example is the silicon substrate. The semiconductor substrate 10 may be a wafer cut out from a semiconductor ingot, or may be a chip obtained by singulating the wafer. The semiconductor ingot may be manufactured by any one of a Czochralski method (CZ method), a magnetic field applied Czochralski method (MCZ method), or a float zone method (FZ method).

The semiconductor substrate 10 has the end side 102 in the top view. When merely referred to as the top view in the present specification, it means that the semiconductor substrate 10 is viewed from an upper surface side. The semiconductor substrate 10 of this example includes two sets of end sides 102 facing each other in the top view. In FIG. 1, the X axis and the Y axis are parallel to any of the end sides 102. In addition, the Z axis is perpendicular to the upper surface of the semiconductor substrate 10. The semiconductor substrate 10 includes an active region 160 and an edge termination structure portion 170.

The active region 160 is a region where a main current flows in the depth direction between the upper surface and the lower surface of the semiconductor substrate 10 during an operation of the semiconductor device 100. An emitter electrode is provided above the active region 160, but is omitted in FIG. 1.

The active region 160 is provided with at least one of a transistor portion 70 including a transistor element such as an IGBT, and a diode portion 80 including a diode element such as a freewheeling diode (FWD). In the example of FIG. 1, the transistor portion 70 and the diode portion 80 are alternately arranged along a predetermined array direction (the X axis direction in this example) on the upper surface of the semiconductor substrate 10.

In FIG. 1, a region where each of the transistor portions 70 is arranged is indicated by a symbol "I", and a region where each of the diode portions 80 is arranged is indicated by a symbol "F". In the present specification, a direction perpendicular to the array direction in the top view may be referred to as an extending direction (the Y axis direction in FIG. 1). Each of the transistor portions 70 and the diode portions 80 may have a longitudinal length in the extending direction. In other words, the length of each of the transistor portions 70 in the Y axis direction is larger than the width in the X axis direction. Similarly, the length of each of the diode portions 80 in the Y axis direction is larger than the width in the X axis direction. The extending direction of the transistor portion 70 and the diode portion 80, and the longitudinal direction of each trench portion described later may be the same.

Each of the diode portions 80 includes a cathode region of N+ type in a region in contact with the lower surface of the semiconductor substrate 10. In the present specification, a region where the cathode region is provided is referred to as the diode portion 80. In other words, the diode portion 80 is a region that overlaps with the cathode region in the top view. A collector region of the P+ type may be provided in a region other than the cathode region on the lower surface of the semiconductor substrate 10.

The transistor portion 70 has the collector region of the P+ type in a region in contact with the lower surface of the semiconductor substrate 10. Further, in the transistor portion 70, an emitter region of the N type, a base region of the P type, and a gate structure having a gate conductive portion and a gate dielectric film are periodically arranged on the upper surface side of the semiconductor substrate 10.

The semiconductor device 100 may have one or more pads above the semiconductor substrate 10. The semiconductor device 100 of this example has a gate pad 112. The semiconductor device 100 may have a pad such as an anode pad, a cathode pad, and a current detection pad. Each pad is arranged close to the end side 102. The region close to the end side 102 refers to a region between the end side 102 and the emitter electrode in the top view. When the semiconductor device 100 is mounted, each pad may be connected to an external circuit through a wiring such as a wire.

A gate potential is applied to the gate pad 112. The gate pad 112 is electrically connected to a conductive portion of a gate trench portion of the active region 160. The semiconductor device 100 includes a gate runner 130 that connects the gate pad 112 and the gate trench portion.

The gate runner 130 is electrically connected to the gate conductive portion of the transistor portion 70 and applies a gate voltage to the transistor portion 70. The gate runner 130 is provided so as to surround an outer periphery of the active region 160 in top view. The gate runner 130 is electrically connected to the gate pad 112 provided in the edge termination structure portion 170.

Further, the semiconductor device 100 may include a temperature sensing portion (not illustrated) that is a PN junction diode formed of polysilicon or the like, and a current detection portion (not shown) that simulates an operation of the transistor portion provided in the active region 160.

The semiconductor device 100 of this example includes an edge termination structure portion 170 between the active region 160 and the end side 102 in top view. The edge termination structure portion 170 of this example is arranged between the gate runner 130 and the end side 102. The edge termination structure portion 170 reduces an electric field strength on the upper surface side of the semiconductor substrate 10. The edge termination structure portion 170 may include at least one of a guard ring, a field plate, and a RESURF which are annularly provided to enclose the active region 160.

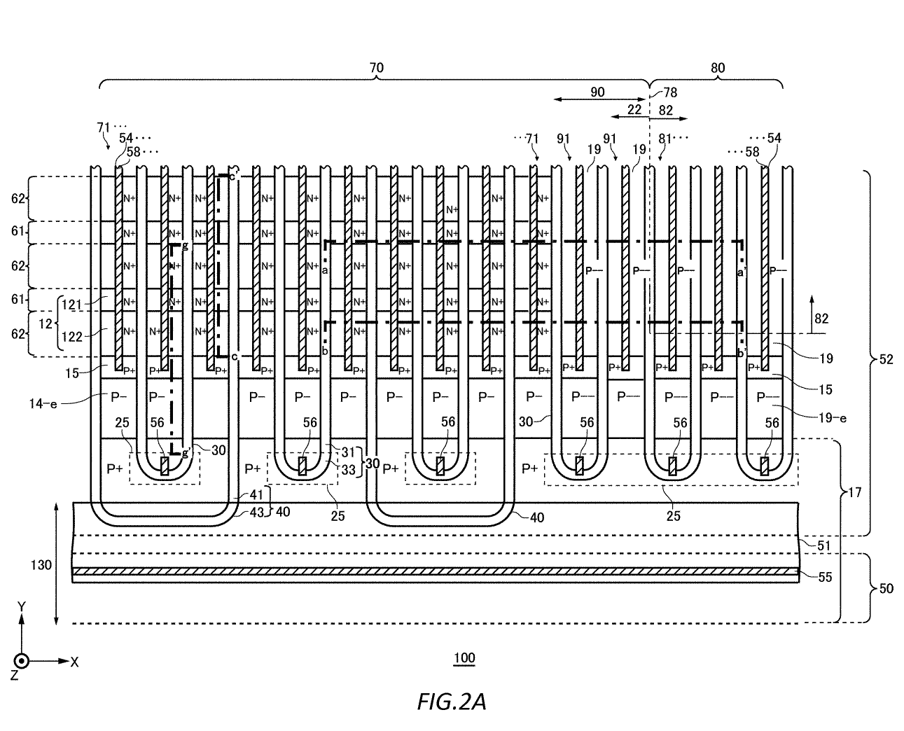

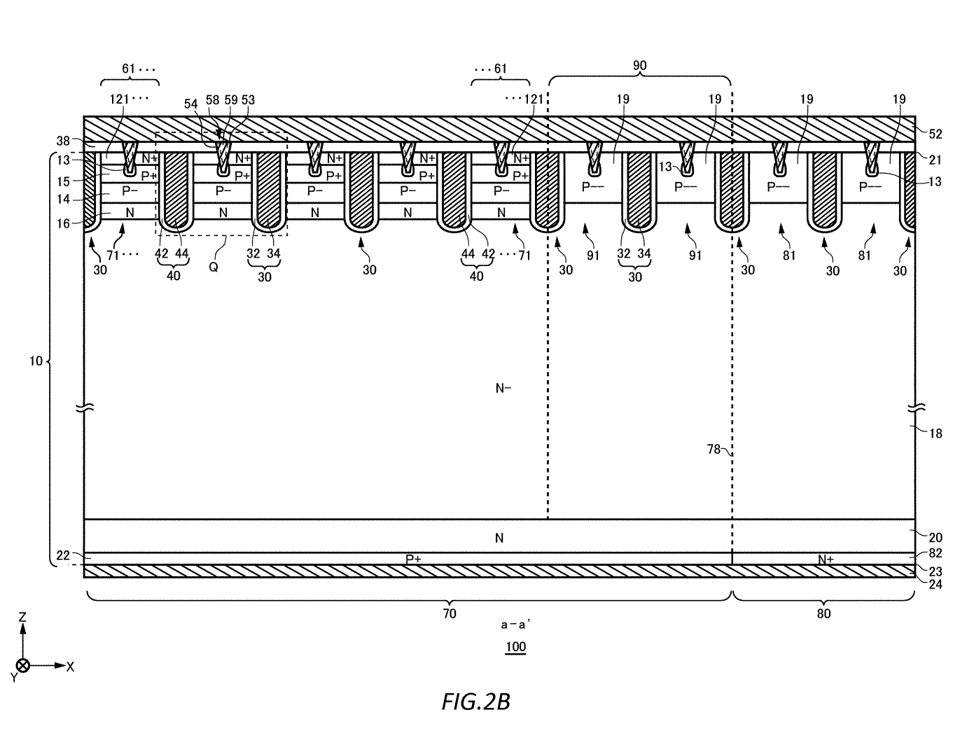

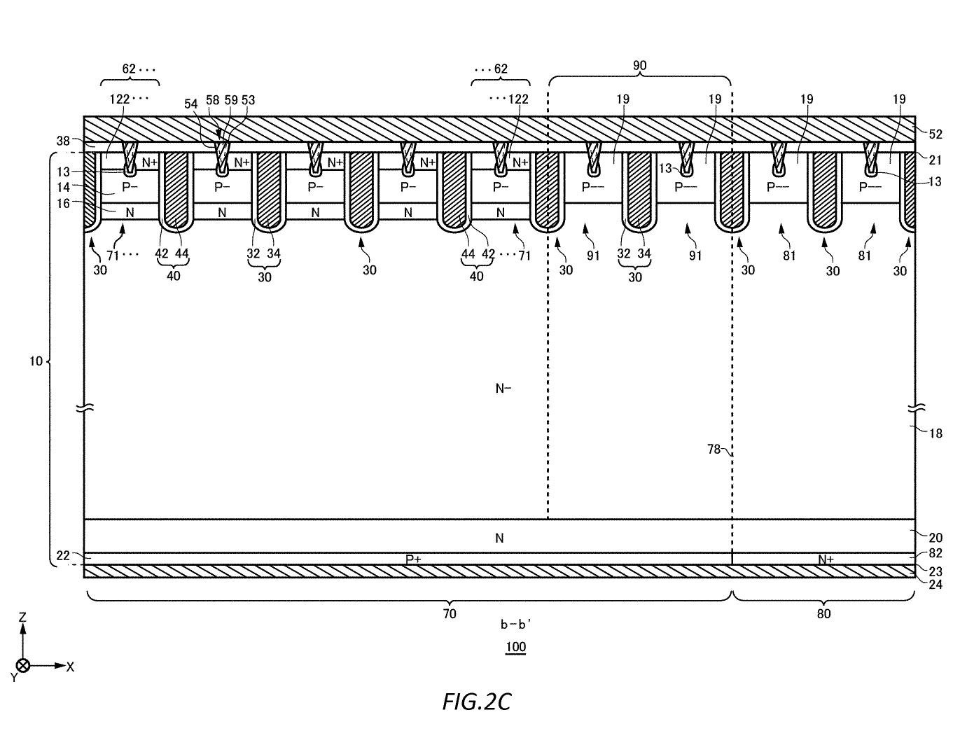

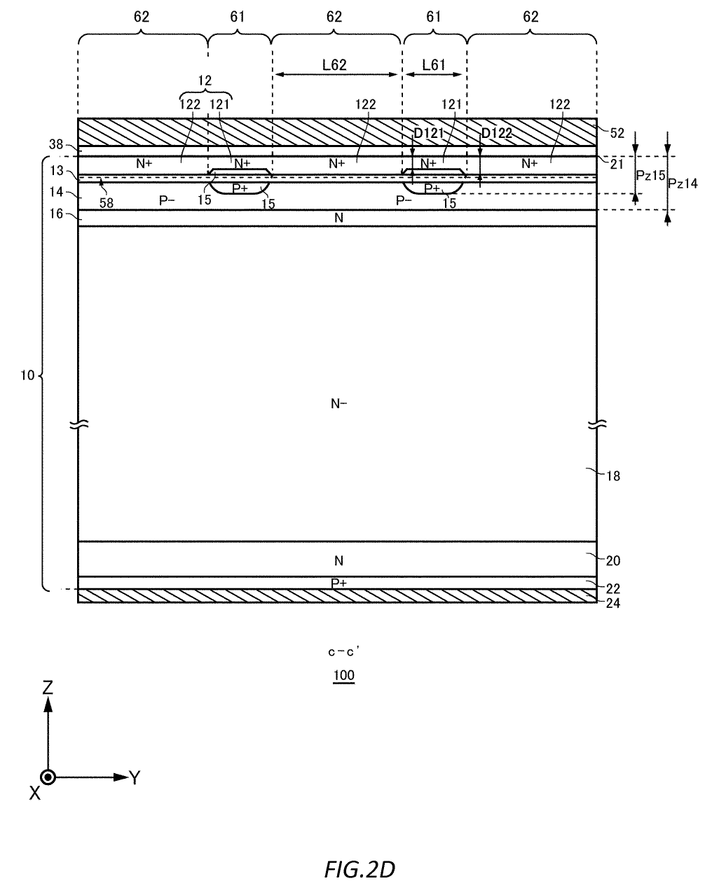

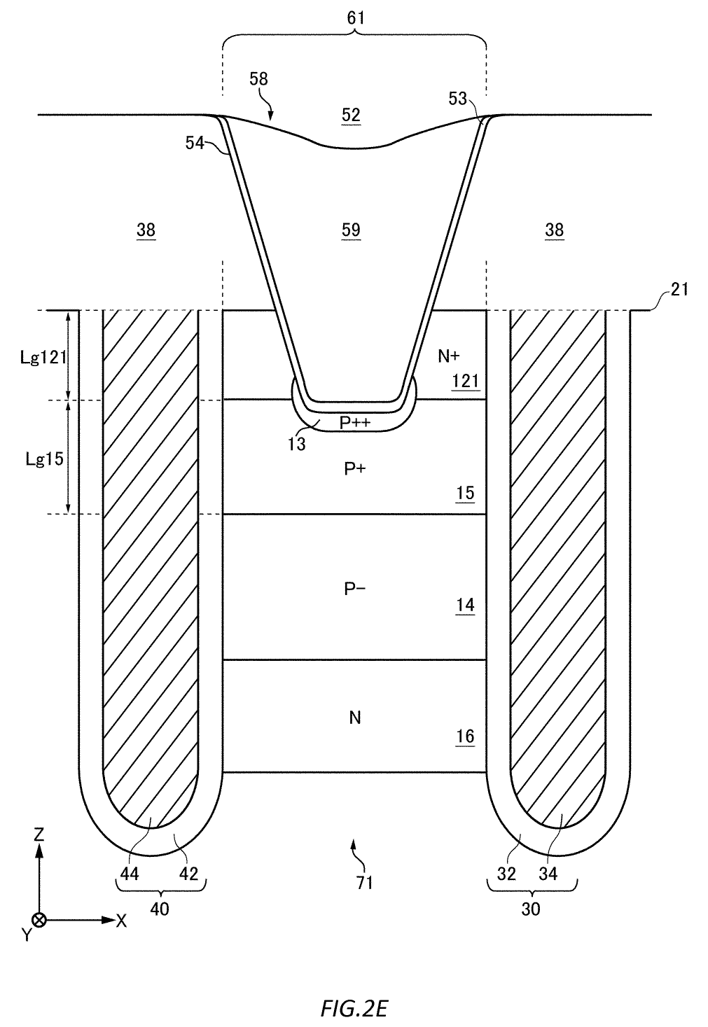

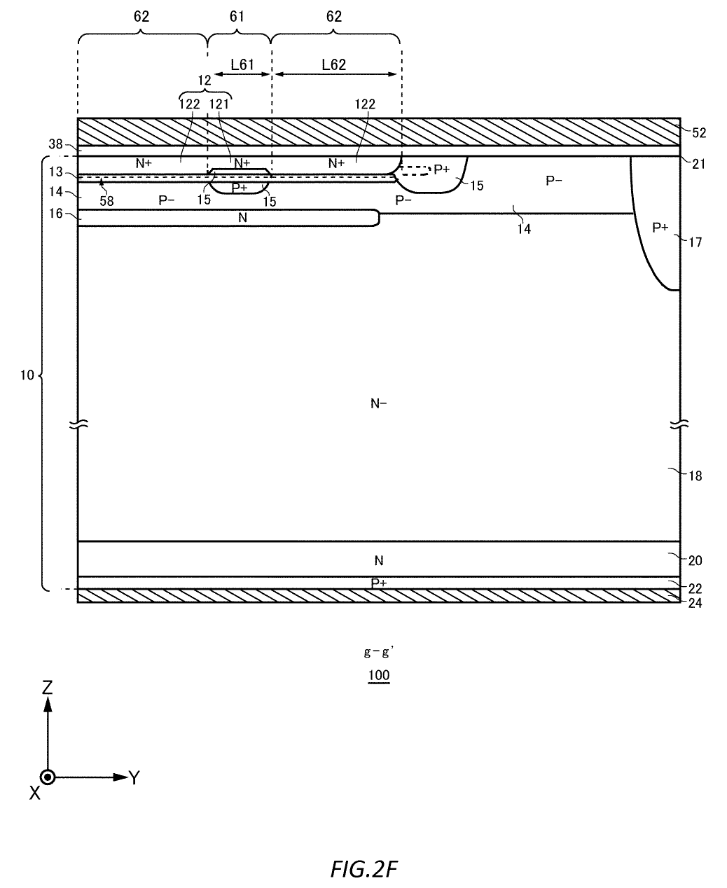

FIG. 2 illustrates an enlarged view of a region A in FIG. 1. The region A is a region including the transistor portion 70, the diode portion 80, and the gate runner 130. The gate runner 130 of this example includes a gate metal layer 50 and a gate runner portion 51.

A boundary region 90 is provided between the transistor portion 70 and the diode portion 80 on the front surface 21 of the semiconductor substrate 10. The front surface 21 of the semiconductor substrate 10 refers to one of the two principal surfaces opposing each other in the semiconductor substrate 10. The front surface 21 will be described below.

The semiconductor device 100 of this example includes a gate trench portion 40, a dummy trench portion 30, a well region 17, an emitter region 12, a base region 14, a contact region 15, and an anode region 19 which are formed inside the front surface 21 side of the semiconductor substrate 10. Further, the semiconductor device 100 of this example includes an emitter electrode 52 and a gate metal layer 50 provided above the front surface 21 of the semiconductor substrate 10. The emitter electrode 52 and the gate metal layer 50 are provided separately from each other.

An interlayer dielectric film is formed between the emitter electrode 52 and the gate metal layer 50, and the front surface 21 of the semiconductor substrate 10, but the interlayer dielectric film is omitted in FIG. 2A. In the interlayer dielectric film of this example, a contact hole 54, a contact hole 55, and a contact hole 56 are formed to pass through the interlayer dielectric film.

The emitter electrode 52 passes the contact holes 54 that are opened in the interlayer dielectric film, and electrically connects with the emitter regions 12, the contact regions 15, the base regions 14 and the the anode region 19 at the front surface 21 of the semiconductor substrate 10. Further, the emitter electrode 52 is connected with dummy conductive portions in the dummy trench portions 30 via the contact hole 56. Between the emitter electrode 52 and the dummy conductive portion, a connection portion 25 formed of a conductive material such as polysilicon doped with an impurity may be provided.

The gate metal layer 50 is in contact with the gate runner portion 51 through the contact hole 55. The gate runner portion 51 is formed of a semiconductor such as polysilicon doped with impurities. The gate runner portion 51 is connected to a gate conductive portion inside the gate trench portion 40 on the front surface 21 of the semiconductor substrate 10.

The emitter electrode 52 and the gate metal layer 50 are formed of a material including metal. At least a part of a region of the emitter electrode 52 may be formed of metal such as aluminum (Al) or of a metal alloy such as an aluminum-silicon alloy (AlSi) or an aluminum-silicon-copper alloy (AlSiCu). At least a partial region of the gate metal layer 50 may be formed of metal such as aluminum (Al) or a metal alloy such as an aluminum-silicon alloy (AlSi) and an aluminum-silicon-copper alloy (AlSiCu). The emitter electrode 52 and the gate metal layer 50 may have a barrier metal formed of titanium, a titanium compound, or the like below a region formed of aluminum or the like. Further, each electrode may include a plug, which is formed by embedding tungsten or the like so as to be in contact with the barrier metal and aluminum or the like, in the contact hole.

The well region 17 is provided overlapping the gate metal layer 50 and the gate runner portion 51. The well region 17 is provided so as to extend with a predetermined width even in a range not overlapping the gate metal layer 50 and the gate runner portion 51. The well region 17 of this example is provided away from an end of the contact hole 54 in the Y axis direction toward the gate metal layer 50. The well region 17 is a second conductivity type region in which the doping concentration is higher than the base region 14. The base region 14 of this example is a P- type, and the well region 17 is a P+ type.

Each of the transistor portion 70 and the diode portion 80 includes a plurality of trench portions arrayed in an array direction on the front surface 21 of the semiconductor substrate 10. In the transistor portion 70 of this example, one or more gate trench portions 40 and one or more dummy trench portions 30 are alternately provided along the array direction. In the diode portion 80 in this example, the plurality of dummy trench portions 30 is provided along the array direction. In the diode portion 80 in this example, the gate trench portion 40 is not provided.

In the transistor portion 70, one or more gate trench portions 40 are arrayed at a predetermined interval along the array direction of each trench. The gate conductive portion inside the gate trench portion 40 is electrically connected to the gate metal layer 50, and a gate potential is applied thereto. In the transistor portion 70, one or more dummy trench portions 30 may be arrayed at a predetermined interval along the array direction. A potential different from the gate potential is applied to the dummy conductive portion inside the dummy trench portion 30. The dummy conductive portion of this example is electrically connected to the emitter electrode 52, and an emitter potential is applied thereto.

In the transistor portion 70, one or more gate trench portions 40 and one or more dummy trench portions 30 may be formed alternately along the array direction. Also, the dummy trench portions 30 are arrayed in the diode portion 80 and the boundary region 90 at a predetermined interval along the array direction. Note that the transistor portion 70 may alternatively be constituted only by the gate trench portion 40 without the dummy trench portion 30 being provided.

The gate trench portion 40 of this example may have two extending portions 41 extending along the extending direction perpendicular to the array direction (portions of a trench that are linear along the extending direction), and a connecting portion 43 connecting the two extending portions 41. The extending direction in FIG. 2A is the Y axis direction.

Preferably, at least a part of the connecting portion 43 is provided in a curved shape in the top view. By the connecting portion 43 connecting the end portions of two extending portions 41 in the Y axis direction to each other, it is possible to reduce the electric field strength at the end portions of the extending portions 41.

In the transistor portion 70, the dummy trench portions 30 are provided between the respective extending portions 41 of the gate trench portions 40. One dummy trench portion 30 may be provided or a plurality of dummy trench portions 30 may be provided between the respective extending portions 41. The dummy trench portion 30 may have a linear shape extending in the extending direction, or may have extending portions 31 and a connecting portion 33 similar to the gate trench portion 40. The semiconductor device 100 may include both of the linear dummy trench portion 30 having no connecting portion 33 and the dummy trench portion 30 having the connecting portion 33. A direction in which the extending portions 41 of the gate trench portion 40 or the extending portions 31 of the dummy trench portion 30 extend to be long in the extending direction is referred to as a longitudinal direction of the trench portion. The longitudinal direction of the gate trench portion 40 or the dummy trench portion 30 may match the extending direction. In this example, the extending direction and the longitudinal direction are the Y axis directions. The array direction in which the plurality of gate trench portions 40 or the dummy trench portions 30 are arrayed is referred to as a lateral direction of the trench portion. The lateral direction may match the array direction. The lateral direction may also be perpendicular to the longitudinal direction. In this example, the lateral direction is perpendicular to the longitudinal direction. In this example, the array direction and the lateral direction are the X axis directions.

In the connecting portion 43 at the tip of the gate trench portion 40, the gate conductive portion inside the gate trench portion 40 are connected to the gate runner portion 51. The gate trench portion 40 may be provided to protrude to the gate runner portion 51 side with respect to the dummy trench portion 30 in the extending direction (Y axis direction). The protruding portion of the gate trench portion 40 is connected to the gate runner portion 51.

A diffusion depth of the well region 17 may be deeper than the depth of the gate trench portion 40 and the dummy trench portion 30. The end portions in the Y axis direction of the gate trench portion 40 and the dummy trench portion 30 are provided in the well region 17 in the top view. In other words, a bottom portion in the depth direction of each trench portion is covered with the well region 17 at an end portion in the Y axis direction of each trench portion. With this configuration, the electric field strength on the bottom portion of each trench portion can be reduced.

A mesa portion is provided between the respective trench portions in the array direction. The mesa portion refers to a region sandwiched between two adjacent trench portions inside the semiconductor substrate 10. As an example, an upper end of the mesa portion is the upper surface of the semiconductor substrate 10. The depth position of the lower end of the mesa portion is the same as the depth position of the lower end of the trench portion. The mesa portion of this example is provided extending in the extending direction (the Y axis direction) along the trench portion, on the upper surface of the semiconductor substrate 10.

The boundary region 90 is provided on the diode portion 80 side in the transistor portion 70. That is, the boundary region 90 is provided adjacent to the diode portion 80 in the transistor portion 70. The boundary region 90 may be a region including the dummy trench portion 30 and provided with a collector region 22 on a back surface side of the semiconductor substrate 10. Each of both end portions, in a trench array direction, of the mesa portion included in the boundary region 90 may be in contact with the dummy trench portion 30. The trench portions of the boundary region 90 may be all dummy trench portions 30. The boundary region 90 may include the gate trench portion 40. In the boundary region 90 of this example, the emitter region 12 of the first conductivity type is not provided in the mesa portion on the front surface 21 side of the semiconductor substrate 10. The boundary region 90 may have the base region 14, or may have an anode region 19 on the front surface 21. The boundary region 90 may have the emitter region 12 or the contact region 15 on the front surface 21. The boundary region 90 of this example has the anode region 19 and the contact region 15 on the front surface 21. Note that FIG. 2A illustrates positions of the collector region 22 and the cathode region 82 provided on the back surface side of the semiconductor substrate 10 when projected onto the front surface 21 side.

A mesa portion 71 is a mesa portion provided in the transistor portion 70. A mesa portion 81 is a mesa portion provided in the diode portion 80. A mesa portion 91 is a mesa portion provided in the boundary region 90. As merely referred to as the mesa portion in the present specification, it may indicate each of the mesa portion 71, the mesa portion 81, or the mesa portion 91. The extending portions of each trench portion may be regarded as one trench portion. That is, the region sandwiched between two extending portions may be set to be a mesa portion.

Each mesa portion is provided with the base region 14 or the anode region 19. In the mesa portion, among the base region 14 or the anode region 19 exposed on the front surface 21 of the semiconductor substrate 10, a region arranged closest to the gate metal layer 50 is defined as the base region 14-e or the anode region 19-e. While the base region 14-e or the anode region 19-e arranged at one end portion of each mesa portion in the extending direction is illustrated in FIG. 2A, the base region 14-e or the anode region 19-e is also arranged at the another end portion of each mesa portion. In each mesa portion, at least one of the emitter region 12 of the first conductivity type or the contact region 15 of the second conductivity type may be provided in a region sandwiched between the base region 14-e or the anode region 19-e in the top view. The emitter region 12 in this example is the N+ type, and the contact region 15 is the P+ type. The emitter region 12 and the contact region 15 may be provided between the base region 14 and the upper surface of the semiconductor substrate 10 in the depth direction.

The mesa portion 71 of the transistor portion 70 includes the emitter region 12 exposed on the front surface 21 of the semiconductor substrate 10. The emitter region 12 is provided in contact with the gate trench portion 40. The mesa portion 71 may be provided with the contact region 15 exposed on the front surface 21 of the semiconductor substrate 10.

The mesa portion 71 of this example has the contact formation region 61 and the contact non-formation region 62. The emitter region 12 has the emitter region 121 and the emitter region 122.

The emitter region 121 is an example of the emitter region 12 provided in the contact formation region 61. The emitter region 122 is an example of the emitter region 12 provided in the contact non-formation region 62. The emitter region 121 and the emitter region 122 may have the same doping concentration.

The contact formation region 61 has the contact region 15. The contact formation region 61 of this example has the emitter region 121 on the front surface 21. The contact formation region 61 may be a region in which the contact region 15 is provided below the emitter region 121 in the sidewall of at least one of a, b, or c trench portions of a plurality of trench portions. The contact formation region 61 may be provided on the sidewall of the gate trench portion 40, or may be provided on the sidewall of the dummy trench portion 30. The contact formation region 61 does not need to function as the inversion layer because the contact formation region 61 has the contact region 15 below the emitter region 121. The contact formation region 61 of this example is provided to extend in the trench array direction from one opposing trench portion to another trench portion.

The contact non-formation region 62 does not have the contact region 15. The contact non-formation region 62 of this example has the emitter region 122 on the front surface 21. The contact non-formation region 62 may be the region in which the contact region 15 is not provided below the emitter region 122 in the sidewall of the gate trench portion 40. Because the contact non-formation region 62 is not provided with the contact region 15 below the emitter region 122, the inversion layer may be formed and electrons may be injected at the time of gate-on. The contact non-formation region 62 of this example is provided to extend in the trench array direction from one opposing trench portion to another trench portion.

A plurality of the contact formation regions 61 may be provided in the mesa portion 71 along the trench extending direction. The emitter region 12 may be continuously provided across the plurality of contact formation regions 61. The contact formation region 61 and the contact non-formation region 62 may be provided alternately in the trench extending direction. The contact formation region 61 may be provided in contact with the contact non-formation region 62. The contact formation region 61 of this example is in contact with the contact non-formation region 62 at both ends in the trench extending direction.

The emitter region 12 is not provided in the mesa portion 81 of the diode portion 80, but the emitter region 12 may be provided. The front surface 21 of the mesa portion 81 of this example is provided with the anode region 19. The front surface 21 of the mesa portion 81 may be provided with the contact region 15. The region sandwiched by the anode region 19-e on the front surface 21 of the mesa portion 81 may be provided with the contact region 15 in contact with each anode region 19-e. The region sandwiched by the contact region 15 on the front surface 21 of the mesa portion 81 may be provided with the anode region 19. The anode region 19 may be arranged, in the trench extending direction, over an entire region sandwiched between the contact regions 15.

The contact hole 54 is provided above each mesa portion. The contact hole 54 is arranged in the region sandwiched between the base region 14-e or the anode region 19-e along the trench extending direction. The contact hole 54 of this example is provided above respective regions of the contact region 15, the base region 14, the anode region 19, and the emitter region 12. The contact hole 54 is not provided in regions corresponding to the base region 14-e, the anode region 19-e, and the well region 17. The contact hole 54 may be arranged at the center of the mesa portion 71 in the trench array direction (X axis direction). The trench contact portion 58 is provided in the contact hole 54. The trench contact portion 58 will be described below.

In the diode portion 80, a cathode region 82 of the N+ type is provided in a region in direct contact with the lower surface of the semiconductor substrate 10. A doping concentration of the cathode region 82 is higher than the doping concentration of the drift region 18. On the lower surface of the semiconductor substrate 10, a collector region of the P+ type 22 may be provided in a region where the cathode region 82 is not provided. The cathode region 82 and the collector region 22 are provided between a back surface 23 of the semiconductor substrate 10 and a buffer region 20 to be described below. In FIG. 2A, a boundary 78 between the cathode region 82 and the collector region 22 is indicated by a broken line.

The cathode region 82 is arranged away from the well region 17 in the Y axis direction. With this configuration, a distance between a region of the P type (well region 17) having a relatively high doping concentration and formed up to a deep position and the cathode region 82 can be secured to improve a breakdown voltage and suppress injection of holes from the well region 17. The end portion in the Y axis direction of the cathode region 82 of this example is arranged farther away from the well region 17 than the end portion in the Y axis direction of the contact hole 54. In another example, the end portion in the Y axis direction of the cathode region 82 may be arranged between the well region 17 and the contact hole 54.

The mesa portion 91 of the boundary region 90 is provided with the anode region 19. The boundary region 90 may include a plurality of the mesa portions 91. The mesa portion 91 may have the base region 14 instead of the anode region 19. The anode region 19 will be described below.

FIG. 2B illustrates an example of an XZ cross section including an a-a’ cross section in FIG. 2A. The XZ cross section including the a-a’ cross section is the XZ plane that passes through the contact formation region 61 in the transistor portion 70. The semiconductor device 100 in this example has the semiconductor substrate 10, the interlayer dielectric film 38, the emitter electrode 52, and the collector electrode 24 in the XZ cross section including the a-a’ cross section. The emitter electrode 52 is provided above the semiconductor substrate 10 and the interlayer dielectric film 38.

The drift region 18 is a region of the first conductivity type which is provided in the semiconductor substrate 10. The drift region 18 in this example is of the N- type as an example. The drift region 18 may be a region which has remained without other doping regions formed in the semiconductor substrate 10. That is, the doping concentration of the drift region 18 may be a doping concentration of the semiconductor substrate 10.

A buffer region 20 is a region of the first conductivity type which is provided on a back surface 23 side of the semiconductor substrate 10 relative to the drift region 18. The buffer region 20 of this example is provided closer to the back surface 23 of the semiconductor substrate 10 than a center of the semiconductor substrate 10 in the depth direction. The buffer region 20 in this example is of the N type as an example. The doping concentration in the buffer region 20 is higher than the doping concentration in the drift region 18. The buffer region 20 may function as a field stopper layer which prevents a depletion layer expanding from the lower surface side of the base region 14 from reaching the collector region 22 of the second conductivity type and the cathode region 82 of the first conductivity type.

The collector region 22 and the cathode region 82 are provided on the back surface 23 of the semiconductor substrate 10. The collector region 22 is provided below the buffer region 20 in the transistor portion 70. The cathode region 82 is provided below the buffer region 20 in the diode portion 80. The boundary 78 between the collector region 22 and the cathode region 82 may be a boundary between the transistor portion 70 and the diode portion 80.

The collector electrode 24 is formed at the back surface 23 of the semiconductor substrate 10. The collector electrode 24 is formed of a conductive material such as metal. At least a partial region of the collector electrode 24 may be formed of metal such as aluminum (Al) or a metal alloy such as an aluminum-silicon alloy (AlSi) or an aluminum-silicon-copper alloy (AlSiCu).

The base region 14 is a region of the second conductivity type which is provided above the drift region 18 in the mesa portion 71. The base region 14 may also be provided in the mesa portion 91. The base region 14 is provided in contact with the gate trench portion 40. The base region 14 may be provided in contact with the dummy trench portion 30.

The anode region 19 is a region of the second conductivity type provided above the drift region 18 in the mesa portion 91 and the mesa portion 81. The anode region 19 is provided in contact with the dummy trench portion 30. The anode region 19 may be provided in contact with the gate trench portion 40. A depth of the anode region 19 may be deeper, shallower, or equal to a depth of the base region 14 in the depth direction of the semiconductor substrate 10. The depth of the anode region 19 in this example is equal to the depth of the base region 14.

The doping concentration of the anode region 19 may be the same as the base region 14, or may be lower than the base region 14. The maximum value of the doping concentration of the anode region 19 may be less than or may be equal to the maximum value of the doping concentration of the base region 14. The maximum value of the doping concentration of the anode region 19 of this example is smaller than the maximum value of the doping concentration of the base region 14. The integrated value obtained by integrating the doping concentration of the anode region 19 along the depth direction of the semiconductor substrate 10 may be smaller than or may be equal to the integrated value obtained by integrating the doping concentration of the base region 14. The integrated value of the doping concentration of the anode region 19 of this example is smaller than the integrated value of the doping concentration of the base region 14.

The emitter region 12 is provided on the front surface 21 side with respect to the drift region 18, and has a higher doping concentration than the drift region 18. The emitter region 12 of this example is provided on the front surface 21. That is, the emitter region 12 of this example is exposed on the front surface 21 of the semiconductor substrate 10. The emitter region 12 of this example is provided above the base region 14 in the mesa portion 71. The emitter region 12 may be provided in contact with the gate trench portion 40. The emitter region 12 may or may not be in contact with the dummy trench portion 30. Note that, the emitter region 12 may not need to be provided in the mesa portion 91.

The contact region 15 is a region of the second conductivity type having a higher doping concentration than the base region 14. The contact region 15 is provided above the base region 14. The contact region 15 of this example is provided below the emitter region 12. In the contact formation region 61, the upper end of the contact region 15 may be in contact with the lower end of the emitter region 12. The entire upper end of the contact region 15 may be in contact with the lower end of the emitter region 12, and some of the upper end of the contact region 15 may be in contact with the lower end of the emitter region 12. In this example, in the contact formation region 61, the entire upper end of the contact region 15 is in contact with the lower end of the emitter region 12. In the contact formation region 61, the contact region 15 may extend in the array direction from one of the two adjacent trench portions to another of the two adjacent trench portions. The contact region 15 may be in contact with the sidewall of at least one of the gate trench portion 40 or the dummy trench portion 30.

An accumulation region 16 is a region of the first conductivity type which is provided on the front surface 21 side of the semiconductor substrate 10 relative to the drift region 18. The accumulation region 16 of this example is of N type as an example. The accumulation region 16 is provided in the mesa portion 71. The accumulation region 16 may be provided in the mesa portion 81 and the mesa portion 91.

In addition, the accumulation region 16 is provided in contact with the gate trench portion 40. The accumulation region 16 may or may not be in contact with the dummy trench portion 30. The doping concentration of the accumulation region 16 is higher than the doping concentration of the drift region 18. Providing the accumulation region 16 can enhance the carrier injection enhancement effect (IE effect) to reduce an ON voltage of the transistor portion 70.

One or more gate trench portions 40 and one or more dummy trench portions 30 are provided at the front surface 21. Each trench portion is provided from the front surface 21 to the drift region 18. In a region where at least any of the emitter region 12, the base region 14, the contact region 15, or the accumulation region 16 is provided, each trench portion also passes through these regions to reach the drift region 18. The configuration of the trench portion passing through the doping region is not limited to the one manufactured in the order of forming the doping region and then forming the trench portion. The configuration of the trench portions passing through the doping region also includes a configuration of forming the trench portions and then forming the doping region between the trench portions.

The gate trench portion 40 has a gate trench, a gate dielectric film 42, and a gate conductive portion 44 which are formed in the front surface 21. The gate dielectric film 42 is formed to cover an inner wall of the gate trench. The gate dielectric film 42 may be formed by oxidizing or nitriding a semiconductor on the inner wall of the gate trench. The gate conductive portion 44 is formed inside the gate trench, and farther inward than the gate dielectric film 42. The gate dielectric film 42 insulates the gate conductive portion 44 from the semiconductor substrate 10. The gate conductive portion 44 is formed of a conductive material such as polysilicon. The gate trench portion 40 is covered by the interlayer dielectric film 38 for the front surface 21.

The gate conductive portion 44 includes a region opposing the adjacent base region 14 in the mesa portion 71 side by sandwiching the gate dielectric film 42 in a depth direction of the semiconductor substrate 10. When a predefined voltage is applied to the gate conductive portion 44, a channel due to an inversion layer of electrons is formed in the surface layer of an interface of the base region 14 that is in contact with the gate trench. On the other hand, the contact region 15 is in contact with the sidewall of the gate trench portion 40 below the emitter region 12. In this case, in a portion, of the sidewall of the gate trench portion 40, that is in contact with the contact region 15, the gate threshold locally becomes high, and a channel portion due to the inversion layer of electrons is not formed. Therefore, in the contact formation region 61, the electrons are not implanted into the drift region 18.

The dummy trench portion 30 may have the same structure as the gate trench portion 40. The dummy trench portion 30 has a dummy trench, a dummy dielectric film 32, and a dummy conductive portion 34 which are formed on the front surface 21 side. The dummy dielectric film 32 is formed covering the inner walls of the dummy trench. The dummy conductive portion 34 is formed inside the dummy trench, and is formed farther inward than the dummy dielectric film 32. The dummy dielectric film 32 insulates the dummy conductive portion 34 from the semiconductor substrate 10. The dummy trench portion 30 is covered by the interlayer dielectric film 38 in the front surface 21.

The interlayer dielectric film 38 is provided on the front surface 21. The emitter electrode 52 is provided above the interlayer dielectric film 38. The interlayer dielectric film 38 is provided with one or more contact holes 54 for electrically connecting the emitter electrode 52 to the semiconductor substrate 10. Similarly, the contact hole 55 and the contact hole 56 may be provided to pass through the interlayer dielectric film 38.

The trench contact portion 58 is provided so as to extend in the depth direction of the semiconductor substrate 10 from the front surface 21 of the semiconductor substrate 10 in the mesa portion between two adjacent trench portions of a plurality of trench portions. The trench contact portion 58 may be provided to extend from an upper end of the interlayer dielectric film 38 to an inside of the semiconductor substrate 10. The trench contact portion 58 of this example is provided in the contact hole 54. The trench contact portion 58 may have the plug portion 59. The plug portion 59 may be of tungsten. The plug portion 59 may be of the same material as the emitter electrode 52. The trench contact portion 58 may have a barrier metal 53 formed of titanium or a titanium compound or the like. The semiconductor device 100 of this example can improve latch-up tolerance by including the trench contact portion 58.

The plug region 13 is provided below the trench contact portion 58. The plug region 13 of this example is in contact with a bottom surface of the trench contact portion 58. The plug region 13 is a second conductivity type region having a higher doping concentration than the base region 14. The plug region 13 of this example has a higher doping concentration than the contact region 15. The doping concentration of the dopant of the second conductivity type in the plug region 13 may be equal to or less than the doping concentration of the dopant of the first conductivity type in the emitter region 12, and may be equal to or greater than the doping concentration of the dopant of the first conductivity type in the emitter region 12. In this example, the doping concentration of the dopant of the second conductivity type in the plug region 13 is lower than the doping concentration of the dopant of the first conductivity type in the emitter region 12.

The plug region 13 may be provided so as to extend in the trench extending direction at the bottom surface of the trench contact portion 58. The plug region 13 may be provided on the entire bottom surface of the trench contact portion 58. The plug region 13 may be formed in a region overlapping a region into which a dopant of the first conductivity type for forming the emitter region 12 is ion-implant, and may be formed in a region overlapping a region into which a dopant of the second conductivity type for forming the contact region 15 is ion implantation. The plug region 13 may also be provided in the boundary region 90 and the diode portion 80.

The bottom surface of the trench contact portion 58 may be deeper than the lower end of the emitter region 12. The bottom surface of the trench contact portion 58 may be shallower than the lower end of the base region 14. The bottom surface of the trench contact portion 58 may be shallower than the lower end of the contact region 15, or may be deeper than the lower end of the contact region 15. The bottom surface of the trench contact portion 58 of this example is deeper than the lower end of the contact region 15.

The semiconductor device 100 of this example does not include a lifetime control unit having a lifetime killer, but may include the lifetime control unit. The semiconductor device 100 may include a lifetime killer region on the front surface 21 side with respect to the center of the semiconductor substrate 10 in the depth direction, or may include the lifetime killer region on the back surface 23 side with respect to the center of the semiconductor substrate 10 in the depth direction.

FIG. 2C illustrates an example of an XZ cross section including a b-b’ cross section in FIG. 2A. The XZ cross section including the b-b’ cross section is an XZ plane passing through the contact non-formation region 62 in the transistor portion 70. In this example, differences from the a-a’ cross section in FIG. 2B passing through the contact formation region 61 will be particularly described. Other features may be the same as those of the a-a’ cross section in FIG. 2B.

The contact non-formation region 62 has, in the mesa portion 71, the emitter region 122, the plug region 13, the base region 14, and the accumulation region 16. The contact non-formation region 62 does not have the contact region 15. The lower surface of the emitter region 122 may be in contact with the upper surface of the base region 14. The bottom surface of the trench contact portion 58 may be deeper than the lower end of the emitter region 122. As will be described below, the lower end of the emitter region 122 may be deeper than the lower end of the emitter region 121.

Below the emitter region 12 in the contact non-formation region 62, the contact region 15 is not provided, and the base region 14 is in contact with the sidewall of the gate trench portion 40. When a predefined voltage is applied to the gate conductive portion 44, the channel due to an electron inversion layer is formed in the surface layer of the interface, of the base region 14, that is in contact with the gate trench portion 40. The inversion layer of electrons is continuously formed from a portion, of the base region 14 in contact with the gate trench portion 40, that is in contact with the bottom surface of the emitter region 12 to a portion, of the base region 14 in contact with the gate trench portion 40, that is in contact with the accumulation region 16. Therefore, the electrons are implanted from the emitter region 12 into the drift region 18.

FIG. 2D illustrates an example of the YZ cross section including the c-c' cross section in FIG. 2A. The YZ cross section including the c-c' cross section is the YZ plane passing through the mesa portion 71 of the transistor portion 70. The c-c' cross section may be the YZ plane passing through the mesa portion 71 between the trench contact portion 58 and the gate trench portion 40. The c-c' cross section is the cross section that does not pass through the contact hole 54, but the bottom surface of the trench contact portion 58 is indicated by a broken line.

The contact formation region 61 is provided, in the trench extending direction, between two adjacent contact non-formation regions 62. The contact non-formation region 62 is provided, in the trench extending direction, between two adjacent contact formation regions 61. At the end adjacent to the contact non-formation region 62 of the contact formation region 61, a step may be provided in the lower end of the emitter region 121.

The length L61 is the width, in the trench extending direction, of the contact formation region 61. The length L61 may be the width, in the trench extending direction, of the contact formation region 61 that is in contact with the gate trench portion 40. The length L61 in the trench extending direction of the contact formation region 61 may be equal to or greater than 0.4 μm and equal to or less than 8.0 μm.

The length L62 is the width, in the trench extending direction, of the contact non-formation region 62. The length L62 may be the width, in the trench extending direction, of the contact non-formation region 62 that is in contact with the gate trench portion 40. The length L62 in the trench extending direction of the contact non-formation region 62 may be equal to or greater than 0.4 μm and equal to or less than 1.9 μm.

The length L62 of the contact non-formation region 62 in the trench extending direction may be greater than the length L61 of the contact formation region 61 in the trench extending direction. However, the length L62 of the contact non-formation region 62 in the trench extending direction may be smaller than the length L61 of the contact formation region 61 in the trench extending direction, or may be the same.

The ratio α is the ratio of the length L62 of the contact non-formation region 62 in the trench extending direction to the length L61 of the contact formation region 61 in the trench extending direction. When the ratio α increases, the proportion of the contact non-formation region 62 that functions as a channel increases, and the channel density increases. When the ratio α decreases, the proportion of the contact non-formation region 62 decreases, and the channel density is reduced. The ratio α may be equal to or greater than 0.2 and equal to or less than 20.

The thickness D121 is the width of the emitter region 121 in the depth direction of the semiconductor substrate 10. The thickness D121 may be the width of the emitter region 121 at the shallowest position of the emitter region 121 in the case where the emitter region 121 has an inclination on a lower surface. The thickness D122 is the width of the emitter region 122 in the depth direction of the semiconductor substrate 10.

The thickness D121 of the emitter region 121 may be smaller than the thickness D122 of the emitter region 122. That is, the lower end of the emitter region 121 may be shallower than the lower end of the emitter region 122. The thickness D121 of the emitter region 121 may be equal to or less than the thickness D122 of the emitter region 122. Since the dopant in the emitter region 121 is less likely to diffuse than the dopant in the emitter region 122 due to an influence by the contact region 15, the emitter region 121 may be formed shallower than the emitter region 122.

The position Pz15 is the distance from the front surface 21 to the lower end of the contact region 15 in the depth direction of the semiconductor substrate 10.

The position Pz14 is a position of the lower end of the base region 14 from the front surface 21 in the depth direction of the semiconductor substrate 10. The position Pz14 may be equal to or greater than the position Pz15.

The position Pz15 may be smaller than the position Pz14. That is, the lower end of the contact region 15 may be shallower than the lower end of the base region 14.

FIG. 2E is an enlarged view illustrating an example of the XZ cross section in the area Q of the transistor portion 70 of the semiconductor device 100 in FIG. 2B. The area Q indicates the vicinity of the mesa portion 71 sandwiched between the dummy trench portion 30 and the gate trench portion 40.

The plug region 13 is in contact with the bottom surface of the trench contact portion 58. In this example, the plug region 13 may be in contact with the sidewall of the trench contact portion 58. The plug region 13 may be in contact with the sidewall of the trench contact portion 58 on the dummy trench portion 30 side, and may be in contact with the sidewall of the trench contact portion 58 on the gate trench portion 40 side. The plug region 13 of this example is in contact with both of the sidewall on the dummy trench portion 30 side and the sidewall on the gate trench portion 40 side of the trench contact portion 58. In this example, the sidewall of the trench contact portion 58 is in contact with the emitter region 121 and the plug region 13.

The length Lg 121 is the length in the depth direction of the emitter region 121 that is in contact with the gate trench portion 40. The length Lg 15 is the length in the depth direction of the contact region 15 that is in contact with the gate trench portion 40 in the contact formation region 61. The length Lg 15 may be larger than the length Lg 121. However, the length Lg 15 may be smaller than the length Lg 121.

FIG. 2F illustrates an example of the YZ cross section including a g-g' cross section in FIG. 2A. The YZ cross section including the g-g' cross section includes, among the YZ plane that passes through the mesa portion 71 of the transistor portion 70, a portion from the end of the contact hole 54 to the well region 17. Other regions may be the same as the c-c' cross section in FIG. 2D. The end of the emitter region 12 in the trench extending direction may be covered with the contact region 15. An end of the plug region 13 in the trench extending direction may be covered with the contact region 15. The contact region 15 provided at the outermost peripheral side in the mesa portion 71 may be in contact with the base region 14, and the base region 14 may be exposed on the front surface 21. The base region 14 exposed on the front surface 21 may be in contact with the well region 17. The end of the accumulation region 16 in the trench extending direction may be positioned below the contact non-formation region 62, may be positioned below the contact region 15 provided at the outermost peripheral side in the mesa portion 71, may be positioned below the base region 14 exposed on the front surface 21, and may be positioned inside the well region 17. In this application, the end of the accumulation region 16 in the trench extending direction is positioned below the contact non-formation region 62.

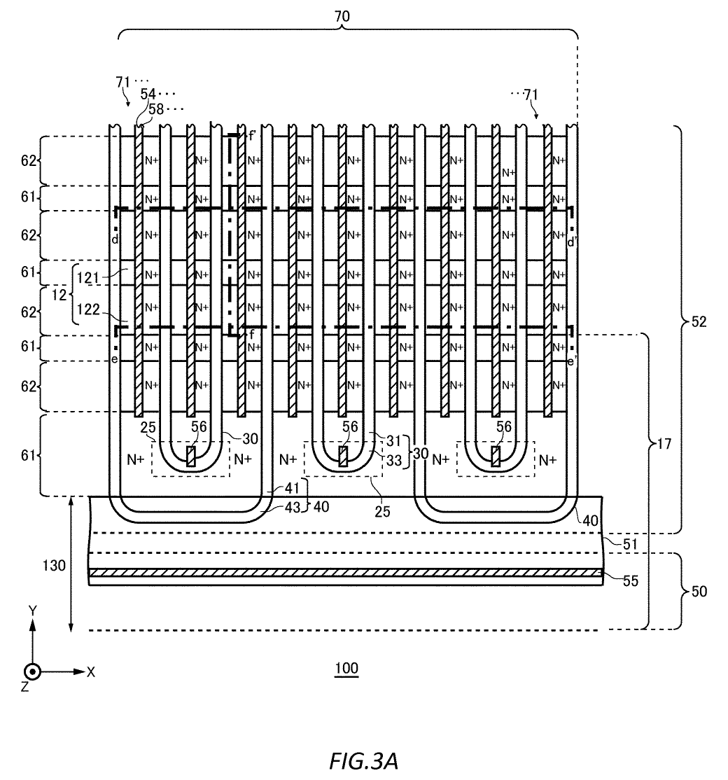

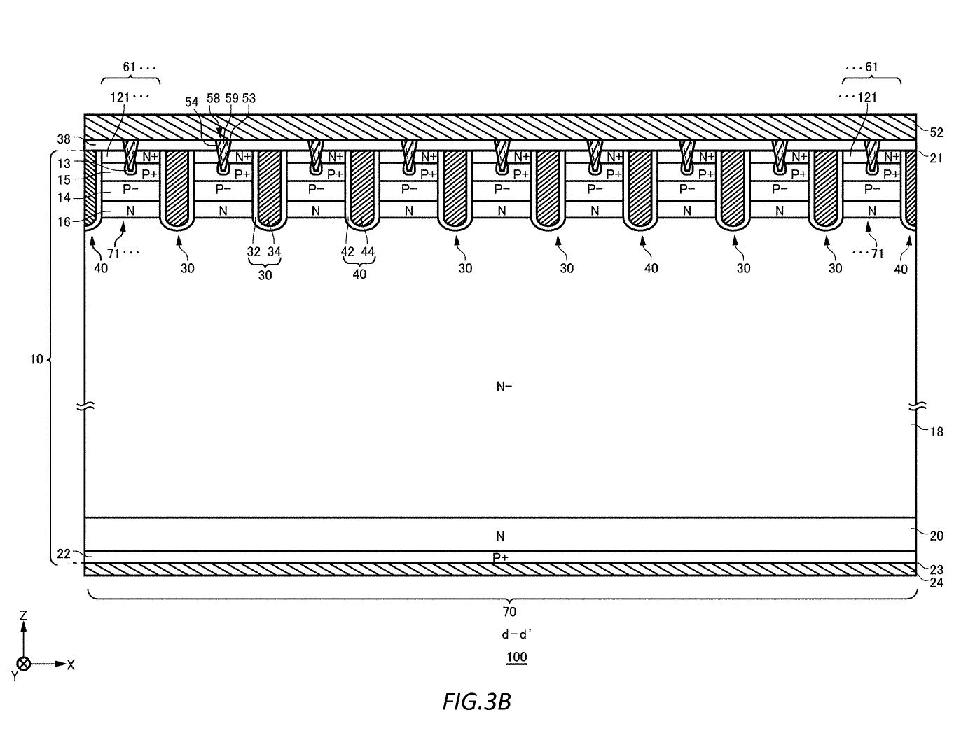

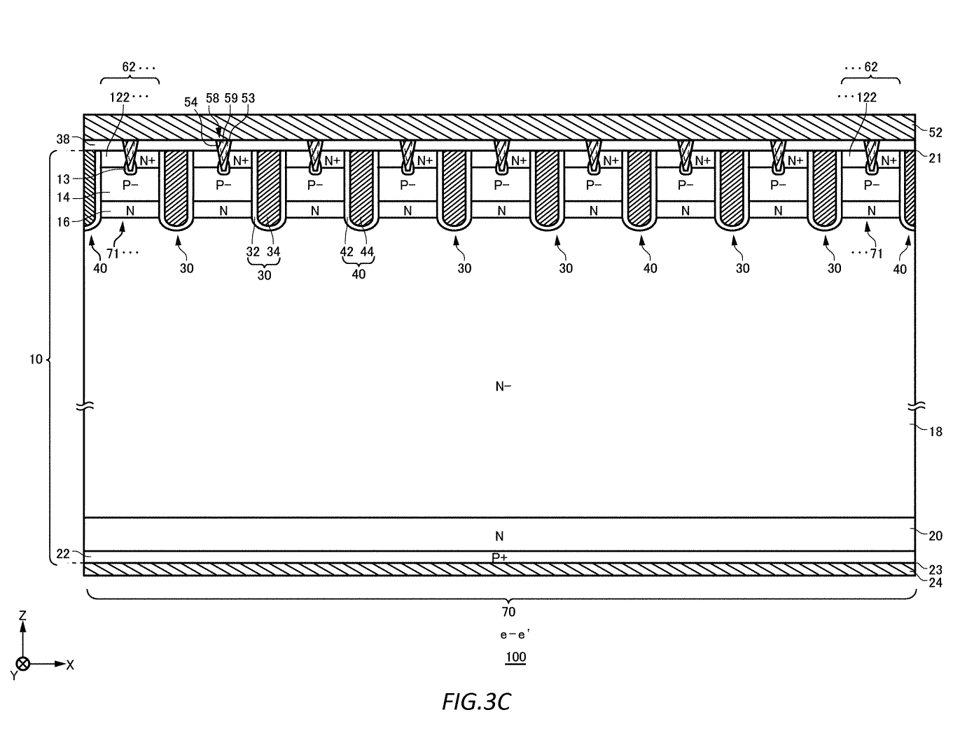

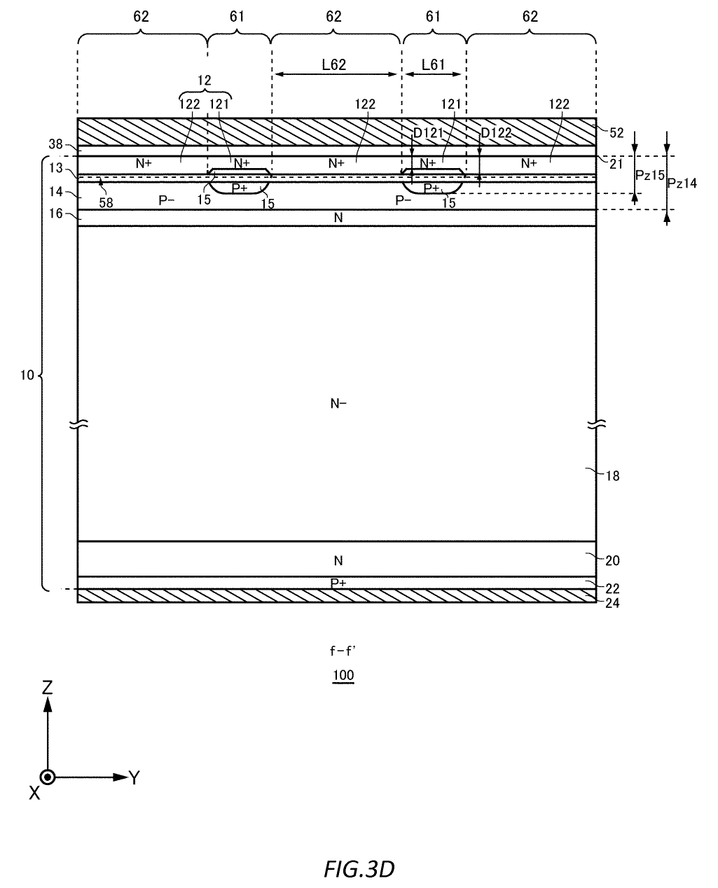

FIG. 3A illustrates the top view of a modification example of the semiconductor device 100. The semiconductor device 100 of this example is the example of an IGBT having the transistor portion 70. The semiconductor device 100 of this example differs from the semiconductor device 100 of FIG. 2A in that the semiconductor device 100 of this example does not include the diode portion 80 and the boundary region 90. In this example, differences from the semiconductor device 100 in FIG. 2A will be particularly described, and other points may be the same as the semiconductor device 100 in FIG. 2A.

In the semiconductor device 100 of this example, a dopant for forming the emitter region 12 may be ion-implanted into the entire surface of the mesa portion 71. In an example, the dopant for forming the emitter region 12 may be ion-implanted without patterning a mask dedicated to the emitter region 12. The dopant for forming the emitter region 12 may be ion-implanted into the entire surface of the semiconductor substrate 10 without using a resist mask. However, in some of the semiconductor substrate 10, the insulating film or the like functions as a mask, and the dopant for forming the emitter region 12 may not be ion-implanted thereto.

The emitter region 12 may be provided in the mesa portion 71 so as to extend in the trench extending direction, and both ends thereof in the trench extending direction may be in contact with the plurality of well regions 17. The doping concentration of the emitter region 12 at the front surface 21 of the semiconductor substrate 10 may be higher than the doping concentration of the well region 17. As in this example, in the portion in which the well region 17 is formed on the back surface 23 side relative to the front surface 21, the contact formation region 61 may also be provided at the front surface 21. In other words, the contact formation region 61 may also be provided above the well region 17. The emitter region 121 and the emitter region 122 may be provided alternately in the trench extending direction between the plurality of well regions 17.

The well region 17 may be provided to extend from an outer side of the mesa portion 71 to the end of the contact hole 54 in the trench extending direction. On the other hand, the end of the contact hole 54 may be positioned inside the contact formation region 61, and may be positioned inside the contact formation region 61 at the outermost end in the Y axis direction. The plurality of well regions 17 may be provided at both ends of the mesa portion 71 in the trench extending direction. That is, the well region 17 may be provided at the end of the mesa portion 71 on the positive side in the Y axis direction, and may be provided at the end of the mesa portion 71 on the negative side in the Y axis direction. In the region in which the well region 17 is formed, the dopant for forming the emitter region 12 may be ion-implanted.

The semiconductor device 100 may include the contact region 15 and the base region 14-e at both ends of the mesa portion 71 in the trench extending direction, as in the semiconductor device 100 of FIG. 2A.

By forming the emitter region 12 in the contact formation region 61 and the contact non-formation region 62, it is possible to avoid the influence of variation in the mask for forming the emitter region 12 and to suppress variation in diffusion of the contact region 15. Accordingly, variation in the emitter region 12 is suppressed, variation in saturation current Isc is reduced, and variation in short-circuit time Tsc can be suppressed.

FIG. 3B illustrates an example of the XZ cross section including the d-d’ cross section in FIG. 3A. The XZ cross section including the d-d’ cross section is an XZ plane passing through the contact formation region 61 in the transistor portion 70. In this example, differences from the a-a’ cross section of FIG. 2B are particularly described, and other points may be the same as the a-a’ cross section of FIG. 2B. The d-d’ cross section of this example differs from the a-a’ cross section of FIG. 2B in that the d-d’ cross section of this example does not have the diode portion 80 and the boundary region 90.

The contact formation region 61 of this example has, in the mesa portion 71, the emitter region 121, the contact region 15, the base region 14, and the accumulation region 16. The contact formation region 61 of this example has the plug region 13, but may not have the plug region 13 on the bottom surface of the trench contact portion 58.

The trench contact portion 58 may be in contact with the emitter region 121 and the contact region 15. The sidewall of the trench contact portion 58 of this example is in contact with the emitter region 121 and the contact region 15. The trench contact portion 58 may be in contact with the emitter region 121 and the contact region 15 at the sidewall opposing the gate trench portion 40. The trench contact portion 58 may be in contact with the emitter region 121 and the contact region 15 at the sidewall opposing the dummy trench portion 30. The bottom surface of the trench contact portion 58 may be in contact with the contact region 15.

FIG. 3C illustrates an example of the XZ cross section including the e-e’ cross section in FIG. 3A. The XZ cross section including the e-e’ cross section is the XZ plane passing through the contact non-formation region 62 in the transistor portion 70. In this example, differences from the b-b’ cross section of FIG. 2C are particularly described, and other points may be the same as the b-b’ cross section of FIG. 2C. The e-e’ cross section of this example differs from the b-b’ cross section of FIG. 2C in that the e-e’ cross section of this example does not have the diode portion 80 and the boundary region 90.

The contact non-formation region 62 of this example has, in the mesa portion 71, the emitter region 122, the base region 14, and the accumulation region 16. The contact non-formation region 62 does not have the contact region 15. The contact non-formation region 62 of this example has the plug region 13, but the contact non-formation region 62 may not have the plug region 13 on the bottom surface of the trench contact portion 58. The lower end of the emitter region 122 may be deeper than the lower end of the emitter region 121.

In a case where the plug region 13 is omitted, the trench contact portion 58 may be in contact with the emitter region 122 and the base region 14. In this case, the trench contact portion 58 may be in contact with the emitter region 122 and the base region 14 at the sidewall opposing the gate trench portion 40. The trench contact portion 58 may be in contact with the emitter region 122 and the base region 14 at the sidewall opposing the dummy trench portion 30. The bottom surface of the trench contact portion 58 may be in contact with the base region 14.

FIG. 3D illustrates an example of the YZ cross section including the f-f' cross section in FIG. 3A. The YZ cross section including the f-f' cross section is the YZ plane that passes through the mesa portion 71 of the transistor portion 70. The f-f' cross section is the cross section that does not pass through the contact hole 54. The bottom surface of the trench contact portion 58 is indicated by a broken line. The f-f' cross section may be the same as the c-c' cross section of FIG. 2D.

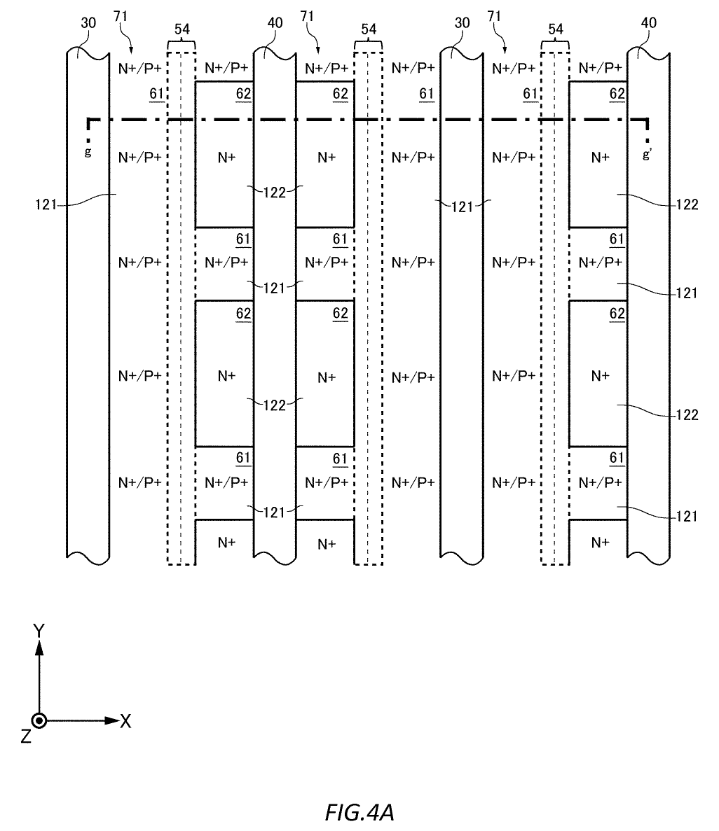

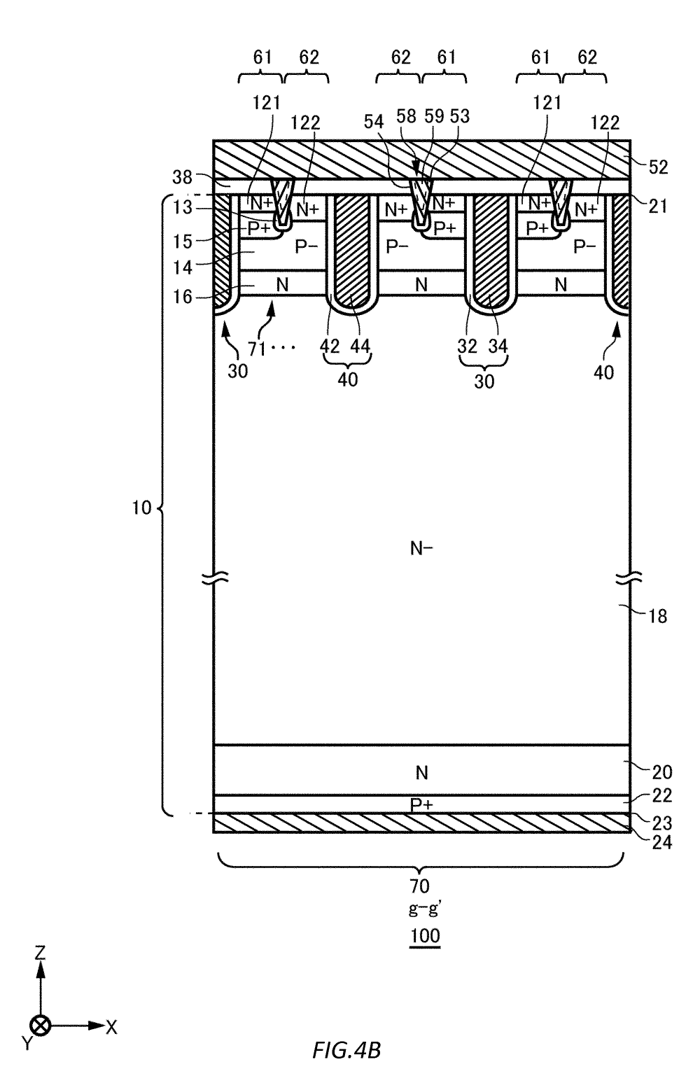

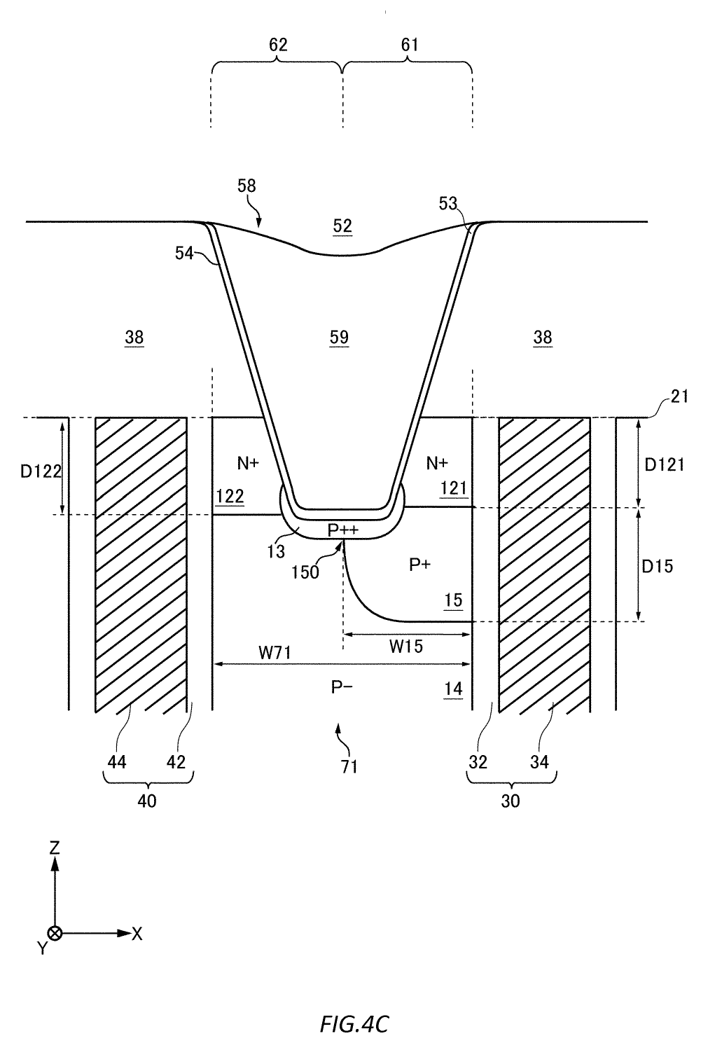

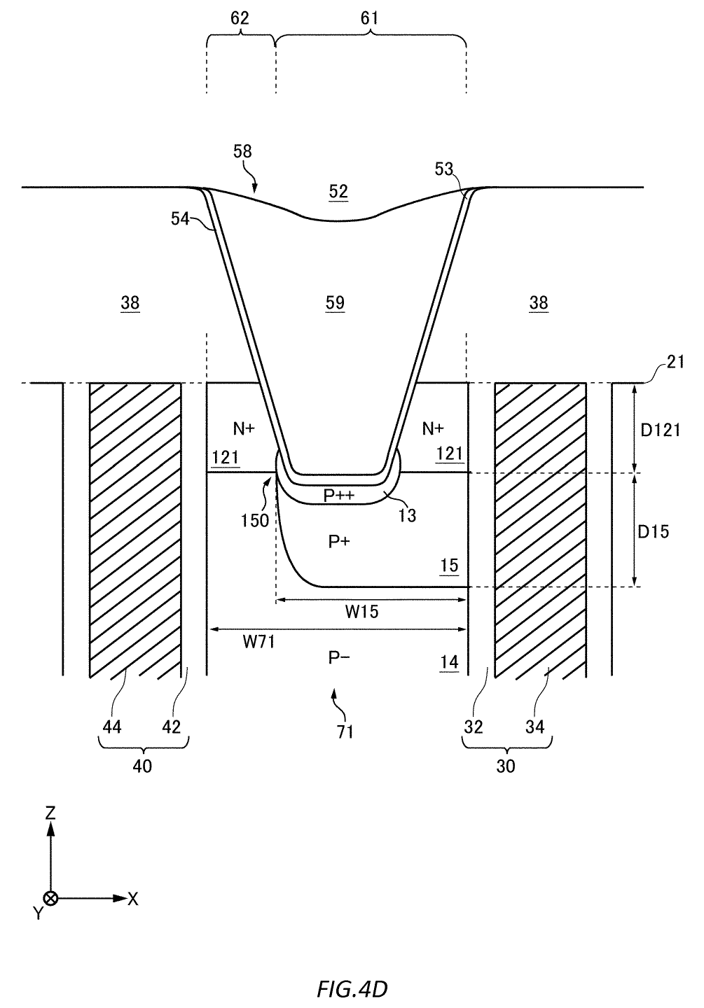

FIG. 4A illustrates a enlarged top view of a modification example of the semiconductor device 100. The region where the contact region 15 is formed in the semiconductor device 100 of this example differs from that in the semiconductor device 100 in FIG. 2A. However, in the semiconductor device 100 of this example, the semiconductor device 100 is common to the semiconductor device 100 in FIG. 2A in that the emitter region 12 is present on the front surface 21. Therefore, the top view of the semiconductor device 100 of this example may be the same as the top view of the semiconductor device 100 in FIG. 2A. In this example, differences from the semiconductor device 100 in FIG. 2A are particularly described.

This drawing illustrates an enlarged top view of the semiconductor device 100 in which the dummy trench portion 30 and the gate trench portion 40 are alternately arrayed. However, the arraying method of the dummy trench portion 30 and the gate trench portion 40 is not limited to this example. The dummy trench portions 30 may oppose each other, or the gate trench portions 40 may oppose each other.

The contact formation region 61 is provided, in the top view, between the dummy trench portion 30 and the contact hole 54. The contact formation region 61 is also provided, in the top view, between the gate trench portion 40 and the contact hole 54. The contact non-formation region 62 is provided, in the top view, between the gate trench portion 40 and the contact hole 54. The contact non-formation region 62 does not have to be provided, in the top view, between the dummy trench portion 30 and the contact hole 54. The contact formation region 61 and the contact non-formation region 62 are provided alternately in the trench extending direction, in the top view, between the gate trench portion 40 and the contact hole 54.

The contact formation region 61 in contact with the sidewall of the dummy trench portion 30 is provided to extend in the trench extending direction. That is, the contact region 15 of this example is provided between the dummy trench portion 30 and the gate trench portion 40 to extend in the trench extending direction. The contact region 15 may be in contact with the base region 14-e at both ends in the trench extending direction, and may be in contact with the well region 17 at both ends in the trench extending direction. In the specification, "N+/P+" indicates that the contact region 15 is provided below the emitter region 12.

The contact formation region 61 in contact with the sidewall of the dummy trench portion 30 may be longer than the width, in the trench extending direction, of the contact formation region 61 in contact with the gate trench portion 40, and may be provided to extend in the trench extending direction. By providing the contact formation region 61 to extend in the trench extending direction at the sidewall of the dummy trench portion 30, latch-up is likely to be suppressed.

The semiconductor device 100 of this example can increase a length, in the trench extending direction, of the contact non-formation region 62 that functions as a channel at the sidewall of the gate trench portion 40, by forming the contact formation region 61 side by side with the contact non-formation region 62 in the trench array direction. Accordingly, the semiconductor device 100 can adjust channel density while suppressing latch-up.

The semiconductor device 100 of this example can adjust saturation current Isc at the time of a short circuit by alteration of the ratio α between the contact formation region 61 and the contact non-formation region 62 at the sidewall of the gate trench portion 40. Therefore, the semiconductor device 100 can adjust saturation current Isc even in the case where gate capacitance Qg is reduced by increasing the ratio of the dummy trench portion 30. The semiconductor device 100 can improve dV/dt controllability at the time of turn-on by reducing gate capacitance Qg. The semiconductor device 100 can reduce on-voltage by improving channel density while securing any gate capacitance Qg.

FIG. 4B illustrates an example of the XZ cross section of the semiconductor device 100 shown in FIG. 4A. The XZ cross section of this example is the XZ plane that passes through the contact formation region 61 and the contact non-formation region 62 in the transistor portion 70. The semiconductor device 100 of this example includes the plug region 13, but it may not include the plug region 13.

The trench contact portion 58 provided between the dummy trench portion 30 and the gate trench portion 40 is in contact with the emitter region 121 and the plug region 13 at the sidewall on the dummy trench portion 30 side, and is in contact with the emitter region 122 and the plug region 13 at the sidewall on the gate trench portion 40 side. In a case wherethe plug region 13 is omitted, the trench contact portion 58 may be in contact with the contact region 15 at the sidewall on the dummy trench portion 30 side.

FIG. 4C is an enlarged view illustrating an example of the XZ cross section of the semiconductor device 100. This drawing illustrates the mesa portion 71 that is sandwiched between the dummy trench portion 30 and the gate trench portion 40.

The contact region 15 extends, in the trench array direction, from the sidewall of the dummy trench portion 30 and terminates below the bottom surface of the trench contact portion 58. That is, the contact region 15 may be provided spaced apart from the gate trench portion 40.

The end 150 represents a position of the contact region 15 farthest from the sidewall of the dummy trench portion 30 in the trench array direction. The end 150 of this example is positioned at the center of the mesa portion 71 in the trench array direction. The end 150 of this example is positioned at the lower end of the plug region 13. The end 150 may be positioned below the bottom surface of the trench contact portion 58.

Thickness D15 is the distance from the upper end to the lower end of the contact region 15 in the depth direction of the semiconductor substrate 10. Thickness D15 may be the distance from the upper end to the lower end of the contact region 15 in the sidewall of the dummy trench portion 30. Thickness D15 may be the distance from the upper end of the contact region 15 that is in contact with the lower end of the emitter region 121 to the lower end of the contact region 15.

Width W15 is the distance from the sidewall of the dummy trench portion 30 to the end 150 of the contact region 15 in the trench array direction. The width W15 of this example is half of the mesa width W71 of the mesa portion 71. The width W15 may be smaller than half of the mesa width W71, and may be larger than half of the mesa width W71.

The contact region 15 extends, in the trench array direction, from the sidewall of the dummy trench portion 30 beyond the bottom surface of the trench contact portion 58, and terminates without extending beyond the end of the plug region 13 on the gate trench portion 40 side.

FIG. 4D is an enlarged view illustrating a modification example of the XZ cross section of the semiconductor device 100. This drawing illustrates the mesa portion 71 that is sandwiched between the dummy trench portion 30 and the gate trench portion 40.

The contact region 15 extends, in the trench array direction, from the sidewall of the dummy trench portion 30 beyond the bottom surface of the trench contact portion 58, and terminates without being in contact with the gate trench portion 40. That is, the end 150 may be spaced apart from the sidewall of the gate trench portion 40. The width W15 of the contact region 15 may be smaller than the width W71 of the mesa portion 71. An increase in the threshold voltage can be suppressed by spacing the contact region 15 apart from the gate trench portion 40.

The contact region 15 of this example extends, in the trench array direction, from the sidewall of the dummy trench portion 30 beyond the bottom surface of the trench contact portion 58, and terminates without extending beyond the plug region 13. The end 150 of the contact region 15 may match the end of the plug region 13 on the gate trench portion 40 side.

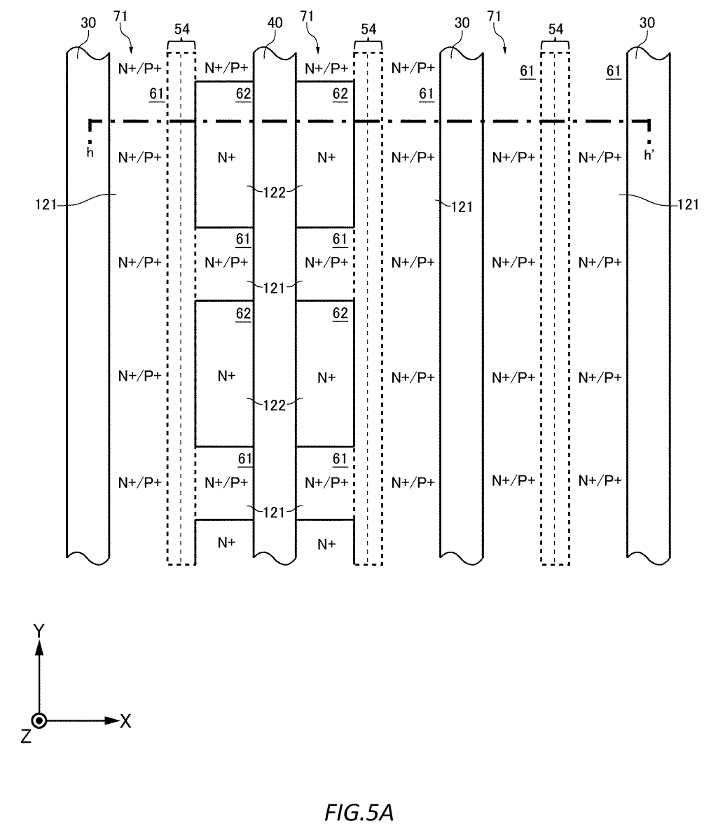

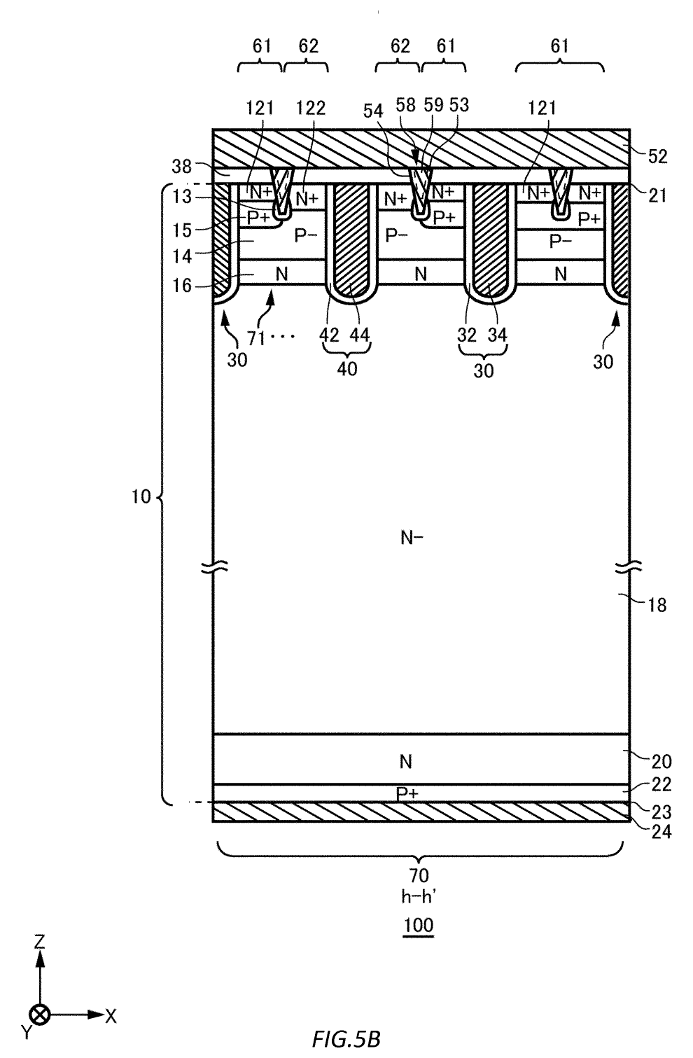

FIG. 5A illustrates a enlarged top view of a modification example of the semiconductor device 100. The semiconductor device 100 of this example differs from the semiconductor device 100 of FIG. 4A in the region in which the contact region 15 is formed. In this example, differences from the semiconductor device 100 in FIG. 4A are particularly described.

The mesa portion 71 sandwiched between two adjacent dummy trench portions 30 is the contact formation region 61. That is, the contact formation region 61 may be provided extending in the trench extending direction in the mesa portion 71 sandwiched between the two adjacent dummy trench portions 30. The mesa portion 71 sandwiched between two adjacent dummy trench portions 30 does not have the contact non-formation region 62. Both ends of the contact formation region 61 in the trench extending direction may be in contact with the plurality of well regions 17, and may be in contact with the plurality of base regions 14-e. That is, the mesa portion 71 sandwiched between two adjacent dummy trench portions 30 may have the contact region 15 over the entire region sandwiched between the base regions 14-e, and may have the contact region 15 over the entire region sandwiched between the well regions 17.

The mesa portion 71 sandwiched between two adjacent dummy trench portions 30 may have the emitter region 12. In this example, the mesa portion 71 sandwiched between two adjacent dummy trench portions 30 has the emitter region 121. The mesa portion 71 sandwiched between two adjacent dummy trench portions 30 may have the emitter region 121 over the entire region sandwiched between the base regions 14-e, and may have the emitter region 121 over the entire region sandwiched between the well regions 17.

FIG. 5B illustrates an example of the XZ cross section of the semiconductor device 100 shown in FIG. 5A. The XZ cross section of this example is the XZ plane that passes through the contact formation region 61 and the contact non-formation region 62 in the transistor portion 70. The semiconductor device 100 of this example includes the plug region 13, but it may not include the plug region 13. In this example, differences from the semiconductor device 100 in FIG. 4B are particularly described.

The trench contact portion 58 provided between two adjacent dummy trench portions 30 may be in contact with the emitter region 121 and the plug region 13 at the sidewall. In the trench contact portion 58 of this example, between two adjacent dummy trench portions 30, both sidewalls are in contact with the emitter region 121 and the plug region 13. In a case where the plug region 13 is omitted, the trench contact portion 58 may have the sidewall and the lower end in contact with the contact region 15.

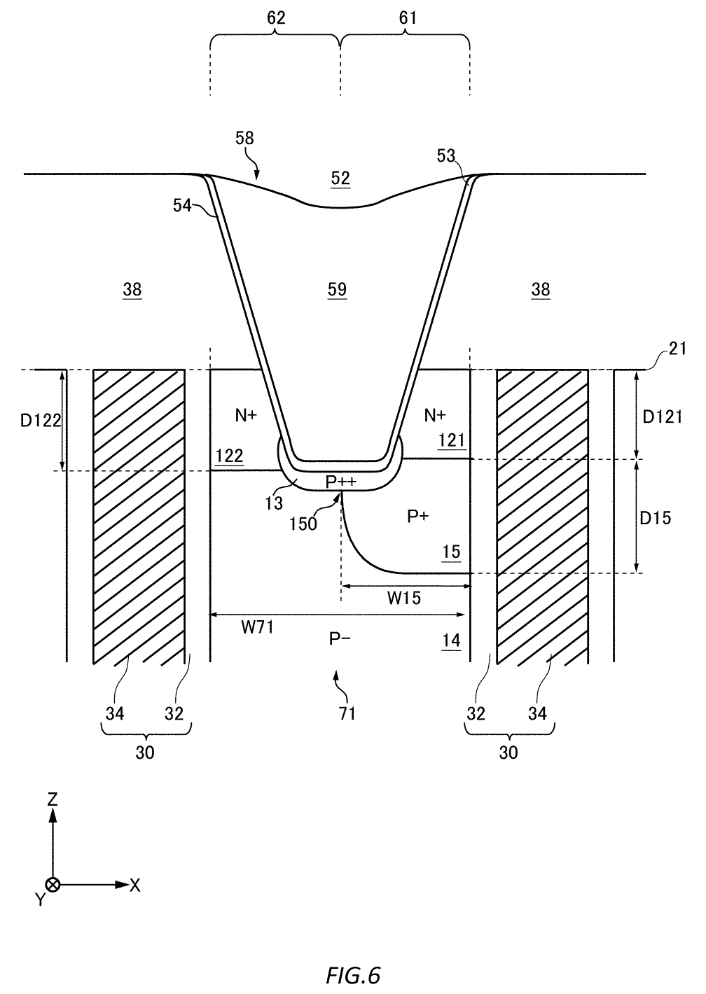

FIG. 6 is an enlarged view illustrating an example of the XZ cross section of the semiconductor device 100. This drawing represents the mesa portion 71 sandwiched between the two adjacent dummy trench portions 30.

In the mesa portion 71 sandwiched between two adjacent dummy trench portions 30, the contact region 15 may be provided in contact with only one dummy trench portion 30 of the two adjacent dummy trench portions 30. Therefore, the thickness D122 of the emitter region 122 becomes larger than the thickness D121 of the emitter region 121. The emitter region 121 is in contact with one dummy trench portion 30, and the emitter region 122 is in contact with another dummy trench portion 30.

The width W15 of this example is half of the mesa width W71, but the width W15 may be larger than half of the mesa width W71 or may be smaller than half of the mesa width W71. Also in the mesa portion 71 sandwiched between two adjacent dummy trench portions 30, the structure of the contact region 15 may be provided such that the end 150 extends to the end of the plug region 13, as illustrated in FIG. 4D.

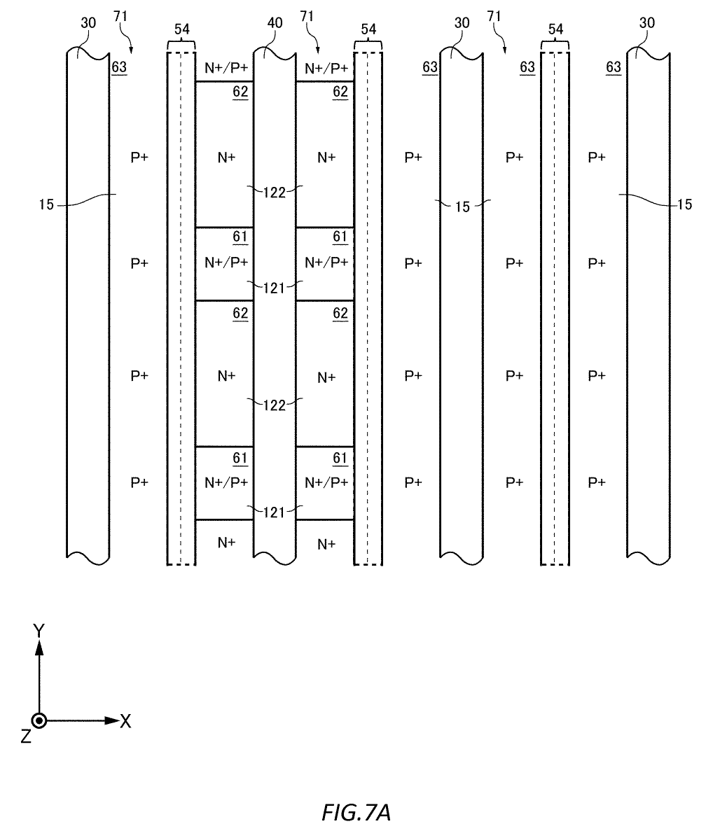

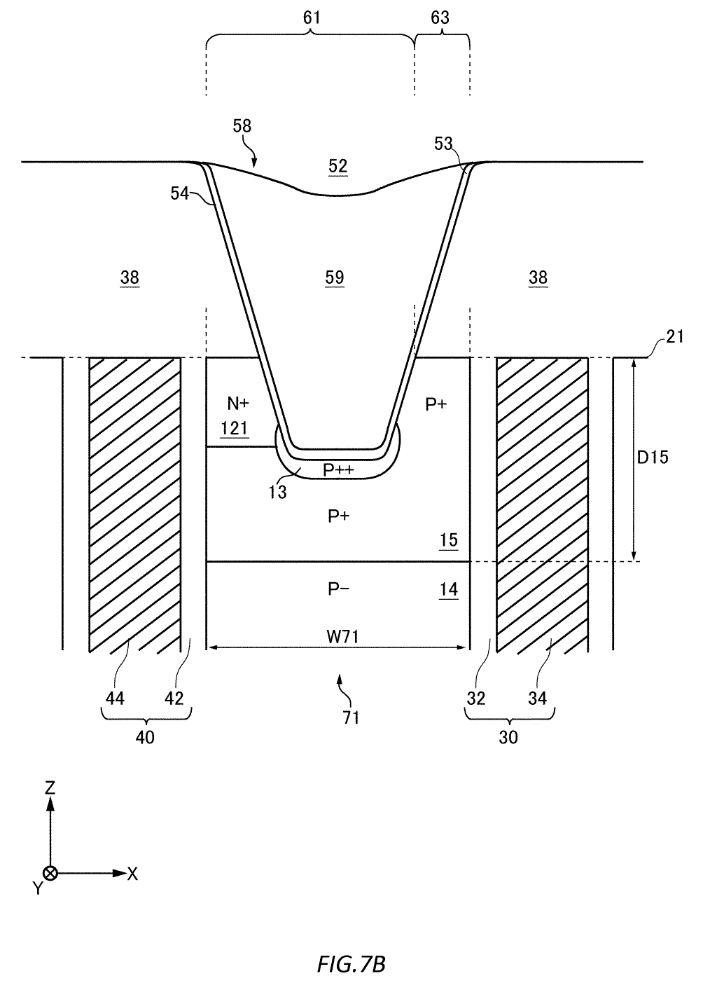

FIG. 7A illustrates a enlarged top view of a modification example of the semiconductor device 100. The semiconductor device 100 of this example differs from the semiconductor device 100 of FIG. 5A in that the semiconductor device 100 of this example includes the emitter region 12 and the contact region 15 on the front surface 21. In this example, differences from the semiconductor device 100 in FIG. 5A are particularly described. The semiconductor device 100 of this example includes a contact exposure region 63.

The contact exposure region 63 is a region where the contact region 15 is provided on the front surface 21 at the sidewall of the dummy trench portion 30. The contact exposure region 63 may not have the emitter region 12. That is, at the sidewall of the dummy trench portion 30, the emitter region 12 may not be provided on the front surface 21. The contact exposure region 63 may be provided spaced apart from the gate trench portion 40.

The contact formation region 61 may be provided in contact with the gate trench portion 40. The contact formation region 61 and the contact non-formation region 62 are alternately provided in the trench extending direction at the sidewall of the gate trench portion 40. By providing the contact exposure region 63, it becomes easier to make the width of the contact non-formation region 62 in the trench extending direction larger than the width of the contact formation region 61 in the trench extending direction.

FIG. 7B is an enlarged view illustrating an example of the XZ cross section of the semiconductor device 100. This drawing illustrates the mesa portion 71 that is sandwiched between the dummy trench portion 30 and the gate trench portion 40. The semiconductor device 100 of this example includes the contact region 15 on the front surface 21 at the sidewall of the dummy trench portion 30.

The contact region 15 extends, in the depth direction of the semiconductor substrate 10, from the front surface 21 to the upper end of the base region 14 at the sidewall of the dummy trench portion 30. The emitter region 121 of this example is not provided at the sidewall of the dummy trench portion 30 above the contact region 15, but is provided at the sidewall of the gate trench portion 40.

Thickness D15 is the distance from the upper end to the lower end of the contact region 15 in the depth direction of the semiconductor substrate 10. The thickness D15 of this example is the distance from the front surface 21 to the lower end of the contact region 15 in the contact exposure region 63.

The trench contact portion 58 is in contact with the emitter region 121 and the plug region 13 at the sidewall on the gate trench portion 40 side. The trench contact portion 58 is in contact with the contact region 15 and the plug region 13 at the sidewall on the dummy trench portion 30 side. The bottom surface of the trench contact portion 58 is in contact with the plug region 13. The plug region 13 may be omitted.

The semiconductor device 100 of this example can reduce latch-up by increasing a region where the contact region 15 is formed while suppressing the influence of mask misalignment of the emitter region 12.

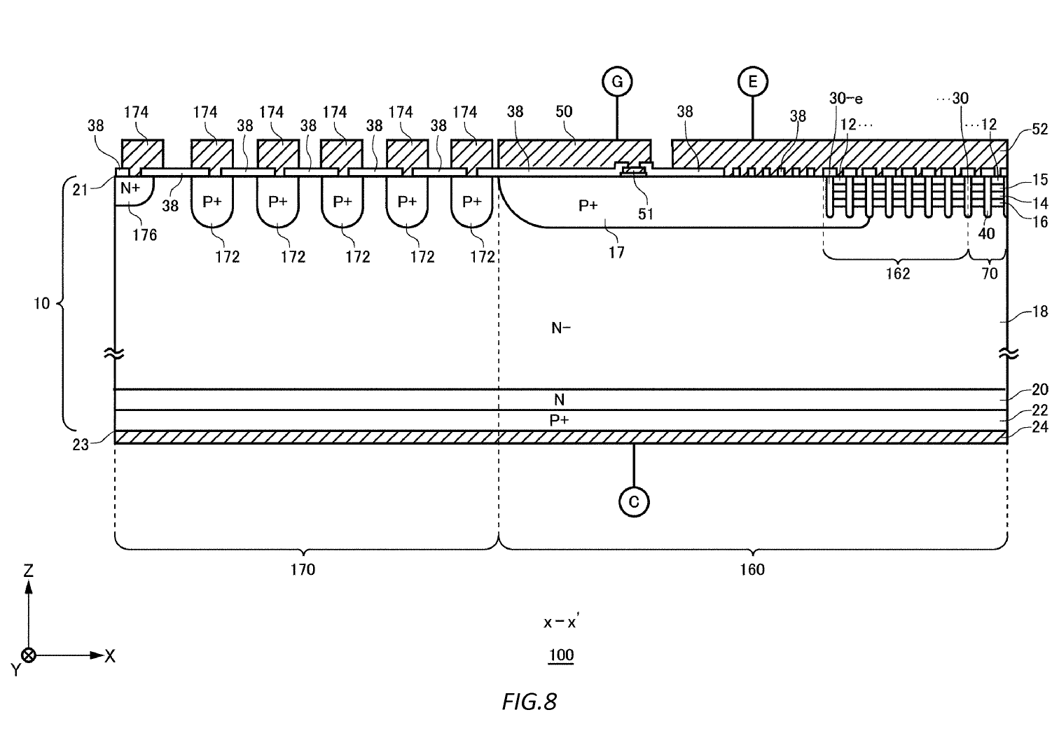

FIG. 8 illustrates an example of the x-x' cross section in FIG. 1. This drawing illustrates the cross section in the vicinity of the edge termination structure portion 170 of the semiconductor device 100. The active region 160 may include the invalid region 162.

The invalid region 162 is provided at the outer periphery of the transistor portion 70. The invalid region 162 may have a plurality of the dummy trench portions 30. The semiconductor device 100 of this example is formed by ion implantation of a dopant in the emitter region 12 into an entire surface of the semiconductor substrate 10 without using a mask. Therefore, the emitter region 12 is provided on the front surface 21 of the semiconductor substrate 10 in the invalid region 162. The contact region 15 may be provided below the emitter region 12 in the invalid region 162.

The dummy trench portion 30-e is the dummy trench portion that is provided closest to the edge termination structure portion 170 in the invalid region 162. The emitter region 12 may be provided on the front surface 21 of the mesa portion in contact with the dummy trench portion 30-e. The sidewall and the bottom surface of the dummy trench portion 30-e may be in contact with the well region 17.

The edge termination structure portion 170 is provided at the outer periphery of the invalid region 162. The edge termination structure portion 170 has the guard ring structure and the channel stopper structure.

The plurality of guard ring portions 172 are an example of the guard ring structure. The plurality of guard ring portions 172 may be provided to surround the active region 160 on the front surface 21. The guard ring portion 172 is the P+ type semiconductor region formed by ion implantation in the vicinity of the front surface 21. The guard ring portion 172 is electrically connected to the electrode layer 174. The electrode layers 174 may be of the same material as the gate metal layer 50 or the emitter electrode 52. A depth of the bottom portion of the guard ring portion 172 may have the same depth as the bottom portion of the well region 17. The depth of the bottom portion of the guard ring portion 172 may be deeper than the depth of the bottom portions of the gate trench portion 40 and the dummy trench portion 30. The plurality of guard ring portions 172 can spread the depletion layer generated in the active region 160 to the outside of the semiconductor substrate 10, thereby preventing electric field strength concentration inside the semiconductor substrate 10 and improving breakdown voltage.

The channel stopper region 176 and the electrode layer 174 are an example of the channel stopper structure. The channel stopper region 176 is electrically connected to the electrode layer 174 via an opening of the interlayer dielectric film 38. The conductivity type of the channel stopper region 176 may be the first conductivity type, or the second conductivity type. The conductivity type of the channel stopper region 176 of this example is teh N+ type. The channel stopper region 176 may terminate the depletion layer generated in the active region 160 at the outside end of the semiconductor substrate 10.

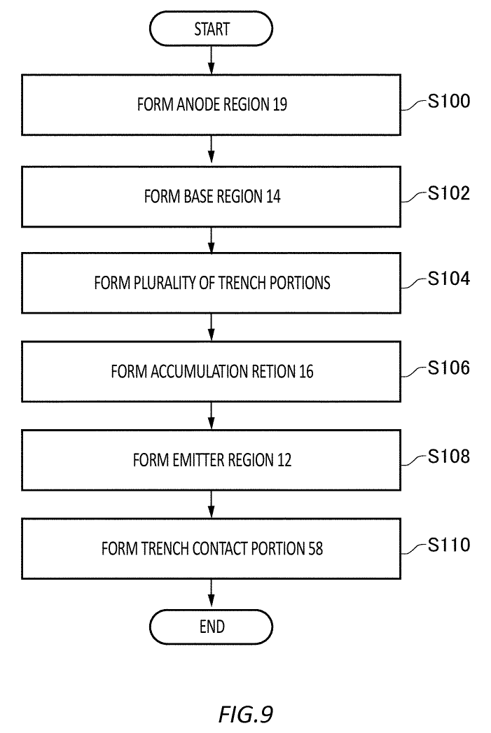

FIG. 9 illustrates an example of a manufacturing method of the semiconductor device 100. In this example, the example of the manufacturing method of the semiconductor device 100 is illustrated, and the order of each step and the like may be subjected to alteration as appropriate.

In step S100, the anode region 19 is formed above the drift region 18. In step S102, the base region 14 is formed above the drift region 18. In a case where the base region 14 and the anode region 19 have the same doping concentration, the base region 14 and the anode region 19 may be formed simultaneously in a common process step. The order of step S100 and step S102 may be reversed.

In step S104, the plurality trench portions are formed on the front surface 21 of the semiconductor substrate 10. The dummy trench portion 30 and the gate trench portion 40 may be formed simultaneously in a common process step, or the dummy trench portion 30 and the gate trench portion 40 may be formed separately. Step S104 may be performed before step 100 and step 102.

In step S106, the accumulation region 16 is formed. In step 108, the emitter region 12 is formed in the front surface 21 of the semiconductor substrate 10. The dopant in the emitter region 12 may be ion-implanted after ion implantation of the dopant in the accumulation region 16, or may be ion-implanted before ion implantation of the dopant in the accumulation region 16. The dopant in the emitter region 12 may be ion-implanted after ion implantation of the dopant in the contact region 15, or may be ion-implanted before ion implantation of the dopant in the contact region 15.

In step S110, the trench contact portion 58 is formed. Before step S110, the interlayer dielectric film 38 may be formed, and the contact hole 54 may be formed. The plug region 13 may be formed, after forming the contact hole 54 of the trench contact portion 58, by ion implantation of a dopant of the second conductivity type into the lower end of the contact hole 54. After forming the plug region 13, the trench contact portion 58 may be formed by filling the contact hole 54 with the barrier metal 53 and the plug portion 59.

The trench contact portion 58 of this example is formed after forming the emitter region 12, but may be formed before forming the emitter region 12.

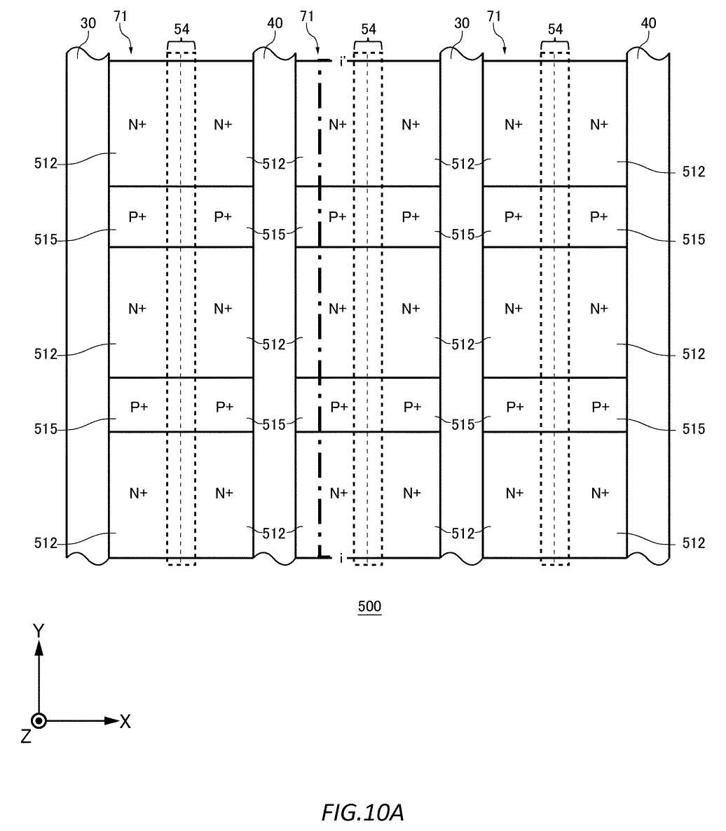

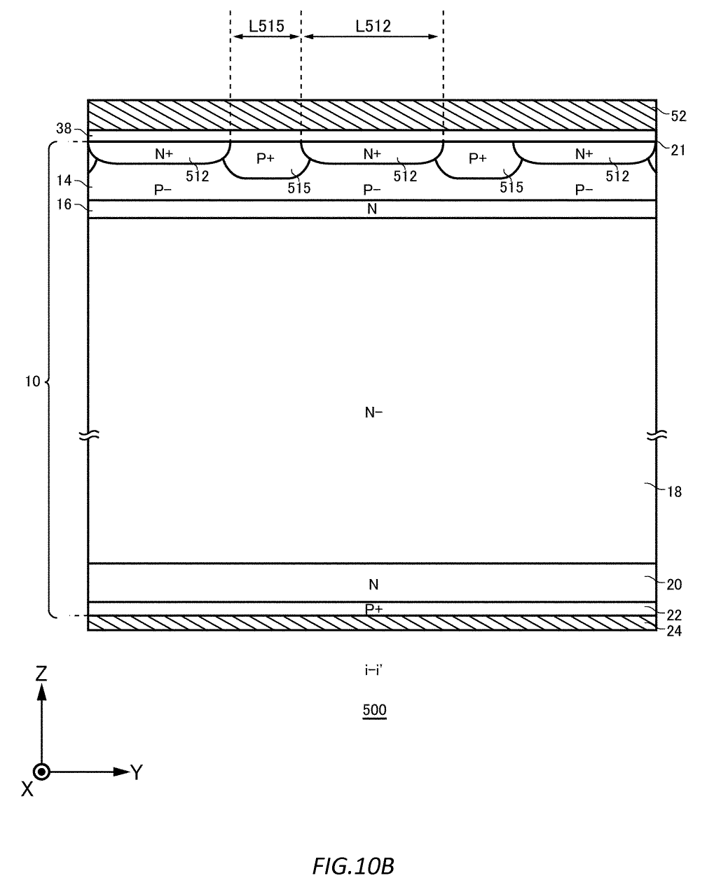

FIG. 10A illustrates a top view of a semiconductor device 500 of a comparative example. The semiconductor device 500 includes the emitter region 512 and the contact region 515. The semiconductor device 500 of this example does not include the trench contact portion 58.

The emitter region 512 and the contact region 515 are alternately provided on the front surface 21 in the trench extending direction. The emitter region 512 extends from the gate trench portion 40 to the dummy trench portion 30 in the trench array direction. The contact region 515 extends from the gate trench portion 40 to the dummy trench portion 30 in the trench array direction.

FIG. 10B illustrates an example of the YZ cross section including the i-i' cross section in FIG. 10A. Although there is a region in which the lower end of the emitter region 512 and the upper end of the contact region 515 partially overlap, the emitter region 512 is not provided above the contact region 515. Therefore, the channel density may vary due to the influence of mask misalignment of both the mask for ion implantation of the dopant in the emitter region 512 and the mask for ion implantation of the dopant in the contact region 515. L512 represents the length, in the trench extending direction, of the emitter region 512 exposed on the front surface 21. L515 represents the length, in the trench extending direction, of the contact region 515 exposed on the front surface 21.

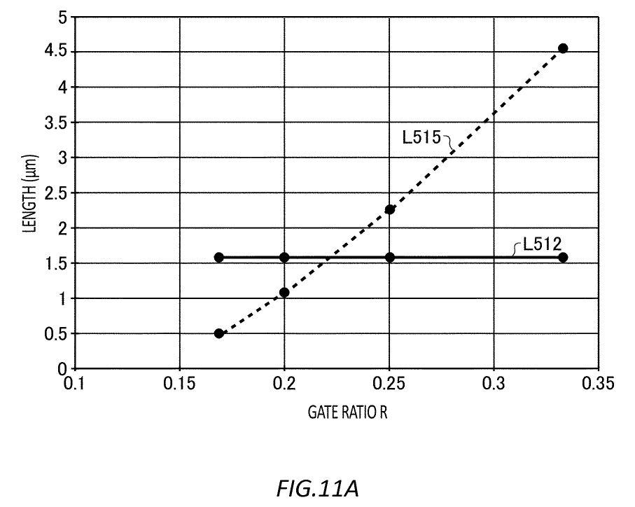

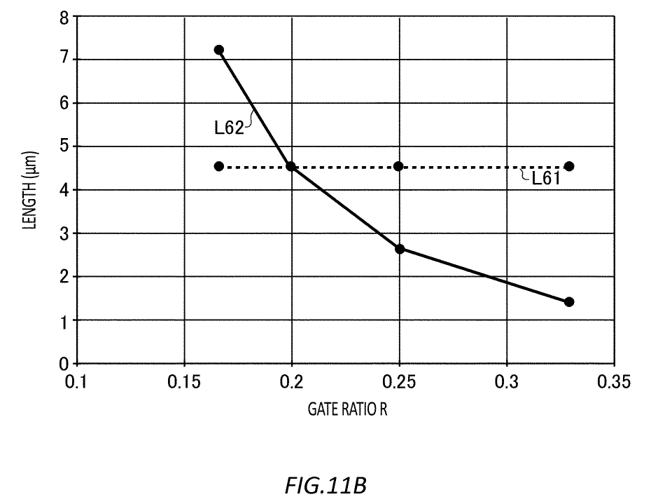

FIG. 11A describes the design method of the semiconductor device 500 of the comparative example. The horizontal axis represents the gate ratio R, and the vertical axis represents lengths (μm) of the length L512 of the emitter region 512 and the length L515 of the contact region 515 in the trench extending direction. The gate ratio R represents the number of gate trench portions relative to the total number of trenches. For example, in the case where the gate ratio R is 0.25, three dummy trench portions are provided for one gate trench portion.

In the semiconductor device 500, in order to keep the saturation current Isc constant when making an alteration of the gate ratio R, it has been necessary to adjust the length L515 of the contact region 515 with the length L512 of the emitter region 512 fixed. In this case, when the proportion of dummy trench portions is increased and the gate ratio R is reduced, it is necessary to reduce the length L515 of the contact region 515 in order to keep the saturation current Isc constant, and the latch-up tolerance may be reduced. Further, in the case where the gate ratio R is made smaller, when attempting to adjust the channel density by reducing the length L515 of the contact region 515 in order to keep the saturation current Isc constant, there is a limit on the minimum dimension of the length L515, and manufacturing limitations may arise. On the other hand, when increasing the saturation current Isc while keeping the gate ratio R constant, it is necessary to reduce a length L515 of the contact region 515. However, also in this case, there is a limit to a minimum dimension of the length L515, and particularly in a case where the gate ratio R is relatively small (for example, 0.25 or less), it is difficult to increase the saturation current Isc while keeping the gate ratio R constant.

FIG. 11B describes an example of a design method of the semiconductor device 100. The horizontal axis indicates the gate ratio R, and the vertical axis indicates lengths (μm) of a length L61 of the contact formation region 61 and a length L62 of the contact non-formation region 62 in the trench extending direction. The semiconductor device 100 can keep the saturation current Isc constant when changing the gate ratio R by adjusting a ratio between the contact formation region 61 and the contact non-formation region 62. In this example, the saturation current Isc can be adjusted by keeping the length L61 of the contact formation region 61 in which the contact region 15 is formed constant and adjusting the length L62 of the contact non-formation region 62. Also, the saturation current Isc may be adjusted by keeping the length L62 constant and adjusting the length of the length L61, or the saturation current Isc may be adjusted by varying both the length L61 and the length L62. For example, in a case where the gate ratio R is made relatively small (for example, 0.25 or less) while keeping the saturation current Isc constant, the length L62 of the contact non-formation region 62 may be increased. By including the trench contact portion 58 that is as deep as or deeper than the emitter region 12, the gate ratio R can be easily reduced without reducing latch-up tolerance.

While the present invention has been described by way of the embodiments, the technical scope of the present invention is not limited to the above-described embodiments. It is apparent to persons skilled in the art that various alterations or improvements can be added to the above-described embodiments. It is also apparent from the described scope of the claims that the embodiments added with such alterations or improvements can be included the technical scope of the present invention.

Note that the operations, procedures, steps, stages, or the like of each process performed by a device, system, program, and method shown in the claims, embodiments, or diagrams can be performed in any order as long as the order is not indicated by "prior to," "before," or the like and as long as the output from a previous process is not used in a later process. Even if the process flow is described using phrases such as "first" or "next" in the claims, embodiments, or diagrams, it does not necessarily mean that the process must be performed in this order.

### Item 1

A semiconductor device comprising:

a drift region of a first conductivity type provided in a semiconductor substrate;

a base region of a second conductivity type provided above the drift region;

an emitter region of the first conductivity type provided on a front surface of the semiconductor substrate and having a doping concentration higher than that of the drift region;

a contact region of the second conductivity type provided above the drift region and having a doping concentration higher than that of the base region;

a trench contact portion extending from the front surface of the semiconductor substrate in a depth direction of the semiconductor substrate; and

a plurality of trench portions extending in a predefined trench extending direction on a front-surface side of the semiconductor substrate,

wherein the plurality of trench portions includes a gate trench portion and a dummy trench portion, and

a mesa portion between the plurality of trench portions has:

a contact formation region in which the contact region is provided below the emitter region on a sidewall of at least one trench portion of the plurality of trench portions; and

a contact non-formation region in which the contact region is not provided below the emitter region on a sidewall of the gate trench portion.rift region of a first conductivity type which is provided in a semiconductor substrate.

### Item 2

The semiconductor device according to Item 1, wherein

the contact formation region is provided on the sidewall of the gate trench portion.

### Item 3

The semiconductor device according to item 1, wherein

the contact formation region is provided on a sidewall of the dummy trench portion.

### Item 4

The semiconductor device according to item 1, wherein

a plurality of the contact formation region is provided in the mesa portion along the trench extending direction, and

the emitter region is provided continuously across the plurality of contact formation regions.

### Item 5

The semiconductor device according to item 1, wherein

the contact formation region and the contact non-formation region are provided alternately in the trench extending direction.

### Item 6

The semiconductor device according to item 1, wherein

a lower end of the emitter region in the contact formation region is shallower than a lower end of the emitter region in the contact non-formation region.

### Item 7

The semiconductor device according to item 1, wherein

in the contact formation region, an upper end of the contact region is in contact with a lower end of the emitter region.

### Item 8

The semiconductor device according to item 1, wherein

in the contact formation region, an entire surface of an upper end of the contact region is in contact with a lower end of the emitter region.

### Item 9

The semiconductor device according to item 1, wherein

in the contact formation region, a length in the depth direction of the contact region in contact with the gate trench portion is greater than a length in the depth direction of the emitter region in contact with the gate trench portion.

### Item 10

The semiconductor device according to item 1, wherein

a ratio of a width in the trench extending direction of the contact non-formation region to a width in the trench extending direction of the contact formation region is equal to or greater than 0.2 and equal to or less than 20.

### Item 11

The semiconductor device according to item 1, wherein

a width in the trench extending direction of the contact formation region is equal to or greater than 0.4 μm and equal to or less than 8.0 μm.

### Item 12

The semiconductor device according to item 1, wherein

a width in the trench extending direction of the contact non-formation region is equal to or greater than 0.4 μm and equal to or less than 1.9 μm.

### Item 13

The semiconductor device according to item 1, wherein

the contact formation region is in contact with the contact non-formation region at both ends in the trench extending direction.

### Item 14

The semiconductor device according to claim 1, comprising

a plurality of well regions of the second conductivity type provided at both ends of the mesa portion in the trench extending direction and having a doping concentration higher than that of the base region,

wherein the emitter region is provided to extend in the trench extending direction in the mesa portion, and both ends in the trench extending direction are in contact with the plurality of well regions.

### Item 15

The semiconductor device according to item 1, comprising

a contact exposure region in which the contact region is provided on the front surface of the semiconductor substrate, on a sidewall of the dummy trench portion.

### Item 16

The semiconductor device according to item 1, wherein

a lower end of the contact region is shallower than a lower end of the base region.

### Item 17

The semiconductor device according to item 1, wherein

the contact region extends, in the trench array direction, from a sidewall of the dummy trench portion and terminates below a bottom surface of a trench contact portion.

### Item 18

The semiconductor device according to item 17, wherein

the contact region extends, in the trench array direction, beyond the bottom surface of the trench contact portion from the sidewall of the dummy trench portion and terminates without being in contact with the gate trench portion.

### Item 19

The semiconductor device according to item 1, wherein

a bottom surface of the trench contact portion is deeper than a lower end of the emitter region and is shallower than a lower end of the base region.

### Item 20

The semiconductor device according to item 1, wherein

the contact formation region in contact with a sidewall of the dummy trench portion is longer than a width, in the trench extending direction, of the contact formation region in contact with the gate trench portion, and is provided to extend in the trench extending direction.

### Item 21

The semiconductor device according to any one of items 1 to 20, comprising

a plug region of the second conductivity type provided below the trench contact portion and having a doping concentration higher than that of the contact region.

### Item 22

The semiconductor device according to item 21, wherein

the plug region is in contact with a bottom surface of the trench contact portion.

### Item 23

The semiconductor device according to item 21, wherein

the plug region is in contact with both a sidewall on on the dummy trench portion side and a sidewall on the gate trench portion side of the trench contact portion.

### Item 24

The semiconductor device according to item 21, wherein

the contact region extends, in the trench array direction, beyond the bottom surface of the trench contact portion from the sidewall of the dummy trench portion, and terminates without extending beyond an end on the gate trench portion side of the plug region.

### Item 25

The semiconductor device according to any one of items 1 to 20, comprising

two adjacent dummy trench portions,

wherein the the emitter region is also provided in a mesa portion sandwiched between the two adjacent dummy trench portions.

### Item 26

The semiconductor device according to item 25, wherein

the mesa portion sandwiched between the two adjacent dummy trench portions is the contact formation region.

### Item 27

The semiconductor device according to item 25, wherein

in the mesa portion sandwiched between the two adjacent dummy trench portions, the contact region is provided in contact with only one dummy trench portion of the two adjacent dummy trench portions.

### Item 28

A semiconductor device according to any one of items 1 to 20, comprising:

a transistor portion;

an invalid region provided at an outer periphery of the transistor portion; and

an edge termination structure portion provided at an outer periphery of the invalid region,

wherein the emitter region is provided on a front surface of the semiconductor substrate in the invalid region.

### Item 29

The semiconductor device according to any one of items 1 to 20, comprising

a transistor portion and a diode portion.

What is claimed is:

1. A semiconductor device comprising:
a drift region of a first conductivity type provided in a semiconductor substrate;
a base region of a second conductivity type provided above the drift region;
an emitter region of the first conductivity type provided on a front surface of the semiconductor substrate and having a doping concentration higher than that of the drift region;
a contact region of the second conductivity type provided above the drift region and having a doping concentration higher than that of the base region;
a trench contact portion extending from the front surface of the semiconductor substrate in a depth direction of the semiconductor substrate; and
a plurality of trench portions extending in a predefined trench extending direction on a front-surface side of the semiconductor substrate,
wherein the plurality of trench portions includes a gate trench portion and a dummy trench portion, and
a mesa portion between the plurality of trench portions has:
a contact formation region in which the contact region is provided below the emitter region on a sidewall of at least one trench portion of the plurality of trench portions; and
a contact non-formation region in which the contact region is not provided below the emitter region on a sidewall of the gate trench portion.

2. The semiconductor device according to claim 1, wherein
the contact formation region is provided on the sidewall of the gate trench portion.

3. The semiconductor device according to claim 1, wherein
the contact formation region is provided on a sidewall of the dummy trench portion.

4. The semiconductor device according to claim 1, wherein
a plurality of contact formation region is provided in the mesa portion along the trench extending direction, and
the emitter region is provided continuously across the plurality of contact formation regions.

5. The semiconductor device according to claim 1, wherein
the contact formation region and the contact non-formation region are provided alternately in the trench extending direction.

6. The semiconductor device according to claim 1, wherein
a lower end of the emitter region in the contact formation region is shallower than a lower end of the emitter region in the contact non-formation region.

7. The semiconductor device according to claim 1, wherein
in the contact formation region, an upper end of the contact region is in contact with a lower end of the emitter region.

8. The semiconductor device according to claim 1, wherein
in the contact formation region, an entire surface of an upper end of the contact region is in contact with a lower end of the emitter region.

9. The semiconductor device according to claim 1, wherein
in the contact formation region, a length in the depth direction of the contact region in contact with the gate trench portion is greater than a length in the depth direction of the emitter region in contact with the gate trench portion.

10. The semiconductor device according to claim 1, wherein
the contact formation region is in contact with the contact non-formation region at both ends in the trench extending direction.

11. The semiconductor device according to claim 1, comprising
a plurality of well regions of the second conductivity type provided at both ends of the mesa portion in the trench extending direction and having a doping concentration higher than that of the base region,
wherein the emitter region is provided to extend in the trench extending direction in the mesa portion, and both ends in the trench extending direction are in contact with the plurality of well regions.

12. The semiconductor device according to claim 1, comprising
sidewalla contact exposure region in which the contact region is provided on the front surface of the semiconductor substrate, on a sidewall of the dummy trench portion.

13. The semiconductor device according to claim 1, wherein
a lower end of the contact region is shallower than a lower end of the base region.

14. The semiconductor device according to claim 1, wherein
the contact region extends, in the trench array direction, from a sidewall of the dummy trench portion and terminates below a bottom surface of a trench contact portion.

15. The semiconductor device according to claim 14, wherein
the contact region extends, in the trench array direction, beyond the bottom surface of the trench contact portion from the sidewall of the dummy trench portion and terminates without being in contact with the gate trench portion.

16. The semiconductor device according to claim 1, wherein
a bottom surface of the trench contact portion is deeper than a lower end of the emitter region and is shallower than a lower end of the base region.

17. The semiconductor device according to claim 1, wherein
the contact formation region in contact with a sidewall of the dummy trench portion is longer than a width, in the trench extending direction, of the contact formation region in contact with the gate trench portion, and is provided to extend in the trench extending direction.

18. The semiconductor device according to claim 1, comprising
a plug region of the second conductivity type provided below the trench contact portion and having a doping concentration higher than that of the contact region.

19. The semiconductor device according to claim 18, wherein
the plug region is in contact with a bottom surface of the trench contact portion.

20. The semiconductor device according to claim 18, wherein
the plug region is in contact with both a sidewall on on the dummy trench portion side and a sidewall on the gate trench portion side of the trench contact portion.
